(19) United States
(12) Patent Application Publication
(10) Pub. No.: US 2026/0068446 A1
(43) Pub. Date: Mar. 5, 2026

(54) DISPLAY PANEL, METHOD FOR MANUFACTURING THE DISPLAY PANEL, AND ELECTRONIC APPARATUS INCLUDING THE DISPLAY PANEL

(71) Applicant: Samsung Display Co., Ltd., Yongin-Si (KR)

(72) Inventors: SEOCKHWAN KANG, Yongin-si (KR); HYUNEOK SHIN, Yongin-si (KR); KEUNWOO KIM, Yongin-si (KR); SUNGHOON YANG, Yongin-si (KR)

(21) Appl. No.: 19/220,723

(22) Filed: May 28, 2025

(30) Foreign Application Priority Data
Aug. 30, 2024 (KR) 10-2024-0117336
Dec. 23, 2024 (KR) 10-2024-0193797

(51) Int. Cl. H10K 59/124; H10H 29/01; H10H 29/32; H10H 29/37; H10H 29/41; H10K 59/12; H10K 59/121; H10K 59/122

(52) U.S. Cl. CPC H10K 59/124; H10H 29/012; H10H 29/32; H10H 29/37; H10H 29/41; H10K 59/1201; H10K 59/1213; H10K 59/1216; H10K 59/122

(57) ABSTRACT

A display panel according to an embodiment may include a base layer, a circuit layer, and a display element layer. The circuit layer may include first to third insulating layers, a capacitor including first and second metal layers, and a transistor. The first metal layer may include a first and a second sub-metal layer, and the second metal layer may include a third and a fourth sub-metal layer. The second sub-metal layer may include a first portion, and a second portion extending from the first portion and disposed within a trench of the insulating layer. The fourth sub-metal layer may include a third portion, and a fourth portion extending from the third portion and disposed within a trench of the insulating layer. On a plane, the second portion and the fourth portion may each extend in one direction perpendicular to the thickness direction.

### CROSS-REFERENCE TO RELATED APPLICATIONS

This U.S. non-provisional patent application claims priority under 35 U.S.C. § 119 of Korean Patent Application Nos. 10-2024-0117336, filed on Aug. 30, 2024, and 10-2024-0193797, filed on Dec. 23, 2024, the entire contents of which are hereby incorporated by reference.

### BACKGROUND

The present disclosure herein relates to a display panel including a capacitor, a method for manufacturing the display panel, and an electronic apparatus including the display panel.

Electronic apparatuses such as smartphones, notebook computers, navigation devices, and smart televisions, which provide images for users, include display devices for displaying images. Electronic apparatuses such as augmented reality devices, virtual reality devices, and video projection devices include display devices that implement high resolution display of images. Research for improving display quality is being carried out on the display devices that implement high resolution display of images.

### SUMMARY

The present disclosure provides a display panel exhibiting excellent reliability and excellent display quality, and an electronic apparatus including the display panel.

The present disclosure also provides a method for manufacturing a display panel exhibiting excellent processibility.

An embodiment of the present disclosure provides a display panel including a base layer, a circuit layer disposed on the base layer, and a display element layer disposed on the circuit layer. The circuit layer includes first to third insulating layers, a capacitor including first and second metal layers, and a transistor. A first trench is defined in the first insulating layer. The second insulating layer is disposed on the first insulating layer. A second and third trenches are defined in the second insulating layer and spaced apart from each other in a first direction perpendicular to a thickness direction. The third insulating layer is disposed on the second insulating layer. A fourth trench is defined in the third insulating layer. The first trench and the second trench are aligned with each other. Likewise the third trench and the fourth trench are aligned with each other. The first metal layer includes a first sub-metal layer and a second sub-metal layer. The second sub-metal layer being partially disposed on the first sub-metal layer. The second sub-metal layer includes a first portion which is spaced apart from the first sub-metal layer with the first and second insulating layers disposed between the first portion and the first sub-metal layer. A second portion of the second sub-metal layer extends from the first portion and is disposed within the first and second trenches. The second metal layer includes a third sub-metal layer disposed on the first sub-metal layer, and a fourth sub-metal layer partially disposed on the third sub-metal layer. The fourth sub-metal layer includes a third portion which is spaced apart from the third sub-metal layer with the second and third insulating layers disposed between the third portion and the third sub-metal layer. A fourth portion of the fourth sub-metal later extends from the third portion and is disposed within the third and fourth trenches. On a plane, each of the second portion and the fourth portion extend in a second direction perpendicular to the thickness direction and orthogonal to the first direction.

In an embodiment, the second portion of the second sub-metal layer may be partially disposed between the first sub-metal layer and the first portion of the second sub-metal layer. The second portion of the second sub-metal layer may electrically connect the first sub-metal layer to the first portion of the second sub-metal layer.

In an embodiment, the fourth portion of the fourth sub-metal layer may be partially disposed between the third sub-metal layer and the third portion of the fourth sub-metal layer. The fourth portion of the fourth sub-metal may electrically connect the third sub-metal layer to the third portion of the fourth sub-metal layer.

In an embodiment, the first portion of the second sub-metal layer may be disposed on a different layer than the third portion of the fourth sub-metal layer.

In an embodiment the first portion of the second sub-metal layer and the fourth portion of the fourth sub-metal layer may be spaced apart from each other in the first direction, with one area of the third insulating layer disposed between the first portion and the fourth portion.

In an embodiment the third sub-metal layer and the second portion of the second sub-metal layer may be spaced apart from each other in the first direction, with one area of the second insulating layer disposed between the third sub-metal layer and the second portion.

In an embodiment, each of the first to third insulating layers may have a single-layer structure.

In an embodiment, the first insulating layer may have a single-layer structure, and the first insulating layer may be directly disposed between the first sub-metal layer and the third sub-metal layer.

In an embodiment, the second insulating layer may have a single-layer structure, and the second insulating layer may be directly disposed between the third sub-metal layer and the first portion of the second sub-metal layer.

In an embodiment, the third insulating layer may have a single-layer structure, and the third insulating layer may be directly disposed between the first portion of the second sub-metal layer and the third portion of the fourth sub-metal layer.

In an embodiment, the transistor may include an oxide semiconductor pattern and a gate disposed on the oxide semiconductor pattern.

In an embodiment, the gate electrode may be formed from the first sub-metal layer.

In an embodiment, the gate electrode, the first portion of the second sub-metal layer, the third sub-metal layer, and the third portion of the fourth sub-metal layer may overlap each other.

In an embodiment, the display element layer may include a light emitting element, and a pixel defining film in which an emission opening is defined, and the light emitting element may include a first electrode having at least a portion in the emission opening, a second electrode disposed over the first electrode, and an emission layer disposed between the first electrode and the second electrode.

In an embodiment of the inventive concept, a method for manufacturing a display panel includes preparing a base layer, forming, on the base layer, a circuit layer including first to third insulating layers, a capacitor including first and second metal layers, and a transistor. The method further includes forming a display element layer on the circuit layer. The first metal layer of the capacitor includes a first sub-metal layer and a second sub-metal layer disposed on the first sub-metal layer, and the second metal layer includes a third sub-metal layer disposed on the first sub-metal layer, and a fourth sub-metal layer disposed on the third sub-metal layer. Forming of the circuit layer includes forming the first sub-metal layer on the base layer, forming a preliminary first insulating layer on the first sub-metal layer, forming the third sub-metal layer on the preliminary first insulating layer, forming the first insulating layer, in which a first trench is defined and forming, on the third sub-metal layer, a preliminary second insulating layer having a second trench aligned with the first trench. Forming the circuit layer may further include forming the second sub-metal layer on the preliminary second insulating layer including filling the first trench and the second trench with the second sub-metal layer material, forming the second insulating layer, including creating the second trench and a third trench from the preliminary second insulating layer and forming, on the second sub-metal layer, the third insulating layer in which a fourth trench is defined, and forming the fourth sub-metal layer on the third insulating layer including filling the third trench and the fourth trench with the fourth sub-metal layer material. The second trench and the third trench are spaced apart from each other in a first direction perpendicular to a thickness direction. The second sub-metal layer includes a first portion and a second portion. The first portion of the second sub-metal layer is created such that is spaced apart from the first sub-metal layer with the first and second insulating layers disposed between the first portion of the second sub-metal layer and the first sub-metal layer. The second portion of the second sub-metal layer is created such that it extends from the first portion of the second sub-metal layer and is disposed within the first and second trenches. The fourth sub-metal layer includes a third portion which is spaced apart from the third sub-metal layer with the second and third insulating layers disposed between the third portion of the fourth sub-metal layer and the third sub-metal layer. The fourth portion is created such that it extends from the third portion of the fourth sub-metal layer and is disposed within the third and fourth trenches. On a plane, each of the second portion and the fourth portion extends in a second direction perpendicular to the thickness direction and orthogonal to the first direction.

In an embodiment, each of the first to third insulating layers may have a single-layer structure.

In an embodiment, the first portion of the second sub-metal layer may be disposed on a different layer from the third portion of the fourth sub-metal layer.

In an embodiment of the inventive concept, an electronic apparatus includes a display panel which provides an image, and a processor, and the display panel includes a base layer, a circuit layer disposed on the base layer, and a display element layer disposed on the circuit layer. The circuit layer includes first to third insulating layers, a capacitor including first and second metal layers, and a transistor. A first trench is defined in the first insulating layer. The second insulating layer is disposed on the first insulating layer, and second and third trenches spaced apart from each other in a first direction perpendicular to a thickness direction are defined in the second insulating layer. The third insulating layer is disposed on the second insulating layer, and a fourth trench is defined in the third insulating layer. The first trench and the second trench are aligned with each other, and the third trench and the fourth trench are aligned with each other. The first metal layer includes a first sub-metal layer and a second sub-metal layer at least partially disposed on the first sub-metal layer. The second sub-metal layer includes a first portion which is spaced apart from the first sub-metal layer with the first and second insulating layers disposed between the first portion and the first sub-metal layer, and a second portion which extends from the first portion and is disposed within the first and second trenches. The second metal layer includes a third sub-metal layer disposed over the first sub-metal layer, and a fourth sub-metal layer at least partially disposed on the third sub-metal layer. The fourth sub-metal layer includes a third portion which is spaced apart from the third sub-metal layer with the second and third insulating layers disposed between the third portion and the third sub-metal layer, and a fourth portion which extends from the third portion and is disposed within the third and fourth trenches. On a plane, each of the second portion and the fourth portion extends in a second direction perpendicular to the thickness direction and orthogonal to the first direction.

In an embodiment, the first portion of the second sub-metal layer may be disposed on a different layer from the third portion of the fourth sub-metal layer.

In an embodiment, the second portion of the second sub-metal layer may be disposed between the first sub-metal layer and the first portion of the second sub-metal layer, and electrically connect the first sub-metal layer to the first portion of the second sub-metal layer.

In an embodiment, the fourth portion of the fourth sub-metal layer may be disposed between the third sub-metal layer and the third portion of the fourth sub-metal layer, and electrically connect the third sub-metal layer to the third portion of the fourth sub-metal layer.

In an embodiment, the first portion of the second sub-metal layer may be disposed on a different layer from the third portion of the fourth sub-metal layer.

In an embodiment, in the first direction, the first portion of the second sub-metal layer and the fourth portion of the fourth sub-metal layer may be spaced apart from each other with one area of the third insulating layer disposed between the first portion and the fourth portion.

In an embodiment, the third sub-metal layer and the second portion of the second sub-metal layer may be spaced apart from each other in the first direction with one area of the second insulating layer disposed between the third sub-metal layer and the second portion.

In an embodiment, each of the first to third insulating layers may have a single-layer structure.

### BRIEF DESCRIPTION OF THE FIGURES

The accompanying drawings are included to provide a further understanding of aspects of the present disclosure, and are incorporated in and constitute a part of this specification. The drawings illustrate embodiments of the present disclosure and, together with the description, serve to explain the principles of the present disclosure. In the drawings:

FIG. 1 is a perspective view of an electronic apparatus according to aspects of the present disclosure.

FIG. 2 is an exploded perspective view of an electronic apparatus according to aspects of the present disclosure.

FIG. 3 is a block diagram of an electronic apparatus according to aspects of the present disclosure.

FIG. 4 is a view illustrating electronic apparatuses according to various aspects of the present disclosure.

FIG. 5 is a cross-sectional view illustrating a portion corresponding to line I-I′ in FIG. 2 according to aspects of the present disclosure.

FIG. 6 is a plan view illustrating a portion of an electronic apparatus according to aspects of the present disclosure.

FIG. 7 is a perspective view of an electronic apparatus according to an aspect of the present disclosure.

FIG. 8 is a cross-sectional view illustrating a portion of an electronic apparatus according to aspects of the present disclosure.

FIG. 9 is an enlarged cross-sectional view illustrating area XX′ in FIG. 7 according to aspects of the present disclosure.

FIG. 10 is a cross-sectional view illustrating a portion of an electronic apparatus according to an aspects of the present disclosure.

FIG. 11 is a perspective view illustrating a portion of an electronic apparatus according to aspects of the present disclosure.

FIG. 12 is a perspective view illustrating a portion of an electronic apparatus according to aspects of the present disclosure.

FIG. 13A is a perspective view illustrating a portion of an electronic apparatus according to aspects of the present disclosure.

FIG. 13B is a perspective view illustrating a portion of an electronic apparatus according to aspects of the present disclosure.

FIG. 14 is a schematic view illustrating a capacitor according to aspects of the present disclosure.

FIG. 15 is a cross-sectional view illustrating a portion of an electronic apparatus according to aspects of the present disclosure.

FIG. 16A is a flowchart illustrating a method for manufacturing a display panel according to aspects of the present disclosure.

FIG. 16B is a flowchart illustrating a method for manufacturing a display panel according to aspects of the present disclosure.

FIG. 17 is a schematic view illustrating a step of manufacturing a display panel according to aspects of the present disclosure.

FIG. 18 is a schematic view illustrating a step of manufacturing a display panel according to aspects of the present disclosure.

FIG. 19 is a schematic view illustrating a step of manufacturing a display panel according to aspects of the present disclosure.

FIG. 20 is a schematic view illustrating a step of manufacturing a display panel according to aspects of the present disclosure.

FIG. 21 is a schematic view illustrating a step of manufacturing a display panel according to aspects of the present disclosure.

FIG. 22 is a schematic view illustrating a step of manufacturing a display panel according to aspects of the present disclosure.

### DETAILED DESCRIPTION

The present disclosure may be modified in various forms, and particular embodiments thereof will be illustrated in the drawings and described herein in detail. The present disclosure should not be construed as limited to the embodiments set forth herein. Rather, these embodiments are provided so that this disclosure will be thorough and complete, and will fully convey the scope of the disclosure to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. The term “and/or” includes one or more combinations which may be defined by relevant elements.

It will be understood that, although the terms “first”, “second”, etc. may be used herein to describe various elements, the elements are not to be limited by these terms. These terms are only used to distinguish one element from another element. For instance, a first element, component, region, layer or section discussed below could be termed a second element, component, region, layer or section without departing from the scope of the inventive concept. Similarly, a second element, component, region, layer, or section could be termed a first element, component, region, layer, or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

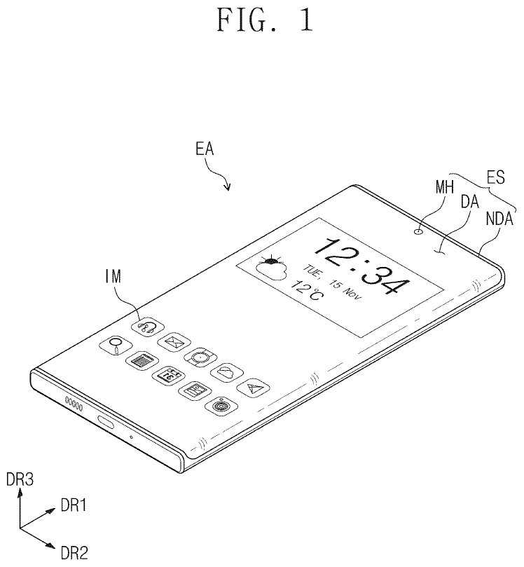

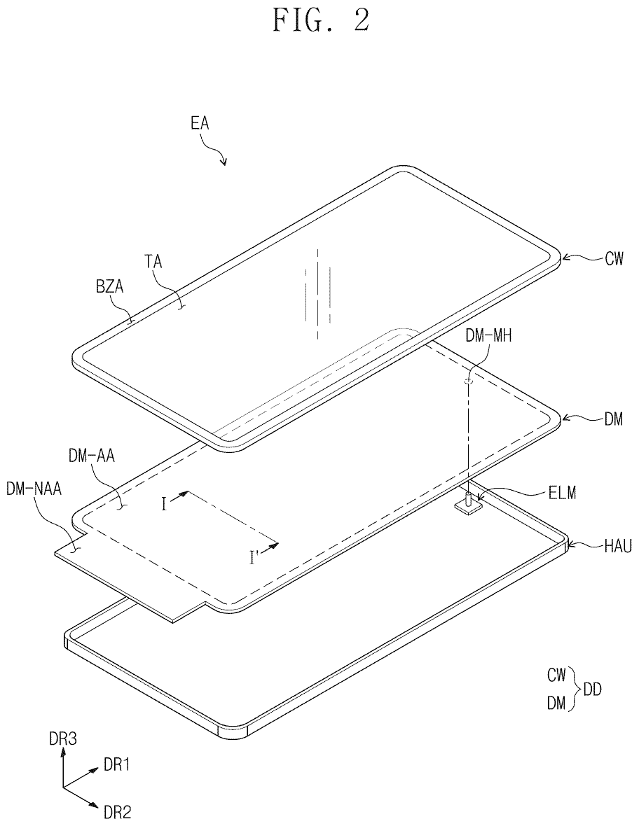

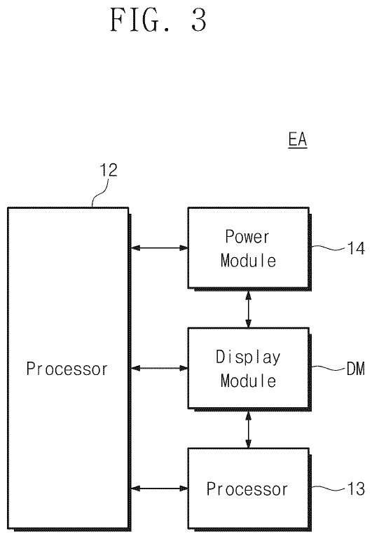

Hereinafter, a display panel and an electronic apparatus including the display panel according to aspects of the present disclosure will be described with reference to the accompanying drawings. FIG. 1 is a perspective view illustrating an electronic apparatus according to aspects of the present disclosure. FIG. 2 is an exploded perspective view of an electronic apparatus according to aspects of the present disclosure. FIG. 3 is a block diagram of an electronic apparatus according to aspects of the present disclosure.

An electronic apparatus EA according to an embodiment illustrated in FIG. 1 may be an apparatus that is activated in response to an electrical signal. For example, the electronic apparatus EA may be a personal computer, a notebook computer, a personal digital assistant, a game console, a portable electronic device, a television, a monitor, an outdoor billboard, a vehicle navigation device, or a wearable device, but an embodiment is not limited thereto. FIG. 1 illustrates a smartphone as an example of the electronic apparatus EA.

The electronic apparatus EA may include a display surface ES defined by a first directional axis DR1 and a second directional axis DR2 orthogonal to the first directional axis DR1. The electronic apparatus EA may provide an image IM for a user through the display surface ES. The electronic apparatus EA may display the image IM toward a direction of a third directional axis DR3 on the display surface ES. The image IM may be reproduced on the display surface parallel to each of the first directional axis DR1 and the second directional axis DR2. The image IM may include not only a dynamic image but also a still image.

Directions indicated by the first to third directional axes DR1, DR2 and DR3 used herein are relative concepts and may be changed to other directions. The directions indicated by the first to third directional axes DR1, DR2 and DR3 may also be referred to as first to third directions, and may be designated by like reference numbers or symbols.

In the present disclosure, the first directional axis DR1 and the second directional axis DR2 perpendicularly cross each other, and the third directional axis DR3 may be a normal direction to a plane defined by the first directional axis DR1 and the second directional axis DR2. A thickness direction of the electronic apparatus EA may be a direction parallel to the third directional axis DR3. The thickness direction of the electronic apparatus EA and the third directional axis DR3 may be designated by like reference numbers or symbols. A front surface (or top surface) and a rear surface (or bottom surface) may oppose each other with respect to the third directional axis DR3, and a normal direction to each of the front surface (or top surface) and the rear surface (or bottom surface) may be parallel to the third directional axis DR3. The front surface (or top surface) indicates a surface adjacent to the display surface ES, and the rear surface (or bottom surface) indicates a surface spaced apart from the display surface ES. An upper side indicates a direction that is closer to the display surface ES, and a lower side indicates a direction that is away from the display surface ES.

As used herein, a cross-section indicates a surface parallel to the thickness direction DR3. A plane indicates a surface which is perpendicular to the thickness direction DR3 and parallel to a plane defined by the first directional axis DR1 and the second directional axis DR2.

As used herein, when a component overlaps another component, it means that the components overlap each other on a plane. In addition, when a component overlaps another component, it is not limited to a case in which the component and the other component have the same surface area and the same shape, and also include a case in which the component and the other component have different surface areas and/or different shapes.

The electronic apparatus EA may sense an external input applied from the outside. The external input may include various types of inputs provided from the outside of the electronic apparatus EA. For example, the external input may include not only a touch by part of the body, such as a user's hand, but also an external input (e.g., hovering) applied by approaching the electronic apparatus EA or being adjacent thereto by a certain distance. In addition, the external input may include various types such as force, pressure, temperature, and light.

The display surface ES may include a display area DA and a non-display area NDA. The display surface ES may further include a sub-area MH. Unlike the illustrated embodiment, the sub-area MH may be omitted.

The display area DA may be an area that is activated in response to an electrical signal. The display area DA may be an area on which the image IM is displayed, and which may sense various types of external inputs.

The display area DA may include a plane defined by the first directional axis DR1 and the second directional axis DR2. The display area DA may include a curved surface bent from at least one side of the plane defined by the first directional axis DR1 and the second directional axis DR2. The electronic apparatus EA, according to an embodiment illustrated in FIG. 1, includes two curved surfaces bent respectively from opposite sides of the plane defined by the first directional axis DR1 and the second directional axis DR2. However, this is illustrative, and a shape of the display area DA is not limited thereto. However, the display area DA may include only the plane defined by the first directional axis DR1 and the second directional axis DR2, or alternatively, the display area DA may include two or more curved surfaces bent respectively from at least two sides of the plane defined by the first directional axis DR1 and the second directional axis DR2, for example, four curved surfaces bent respectively from four sides.

The electronic apparatus EA according to an embodiment may be flexible. The term “flexible” indicates a characteristic of being capable of bending, and may include any implementation from a fully folded structure to a structure capable of bending at the level of several nanometers. For example and without limitation, the electronic apparatus EA may be a rigid apparatus. Alternatively, the electronic apparatus EA may be a fully foldable apparatus.

The non-display area NDA may have a certain color. The non-display area NDA may be an area adjacent to the display area DA. The non-display area NDA may surround the display area DA. Accordingly, a shape of the display area DA may be substantially defined by the non-display area NDA. However, this is illustrated as an example, and the non-display area NDA may be arranged to be adjacent to only one side of the display area DA, or may be omitted. The display area DA may be provided in various shapes, and is not limited to any one embodiment.

The sub-area MH may sense an external subject received through the display surface ES, or provide the outside with a sound signal such as voice, through the display surface ES. A light signal such as visible light or infrared light may travel to the sub-area MH.

The sub-area MH may be disposed within the display area DA. However, this is illustrative, and an arrangement of the sub-area MH is not limited to any one embodiment. For example, the sub-area MH may be surrounded by the non-display area NDA or alternatively, surrounded by the display area DA and the non-display area NDA. FIG. 1 illustrates one sub-area MH, but the sub-area MH may be provided in plurality.

Various second electronic modules ELM (see FIG. 2) may be arranged to correspond to the sub-area MH. For example, the second electronic modules (see FIG. 2) may include at least one of a camera, a speaker, a light detecting sensor, or a heat detecting sensor. The electronic apparatus EA may include the second electronic module (see FIG. 2) which transduces an external image using visible light passing through the sub-area MH, or determines the approach of an external object using infrared light. The second electronic module (see FIG. 2) may include a plurality of components, and is not limited to any one embodiment.

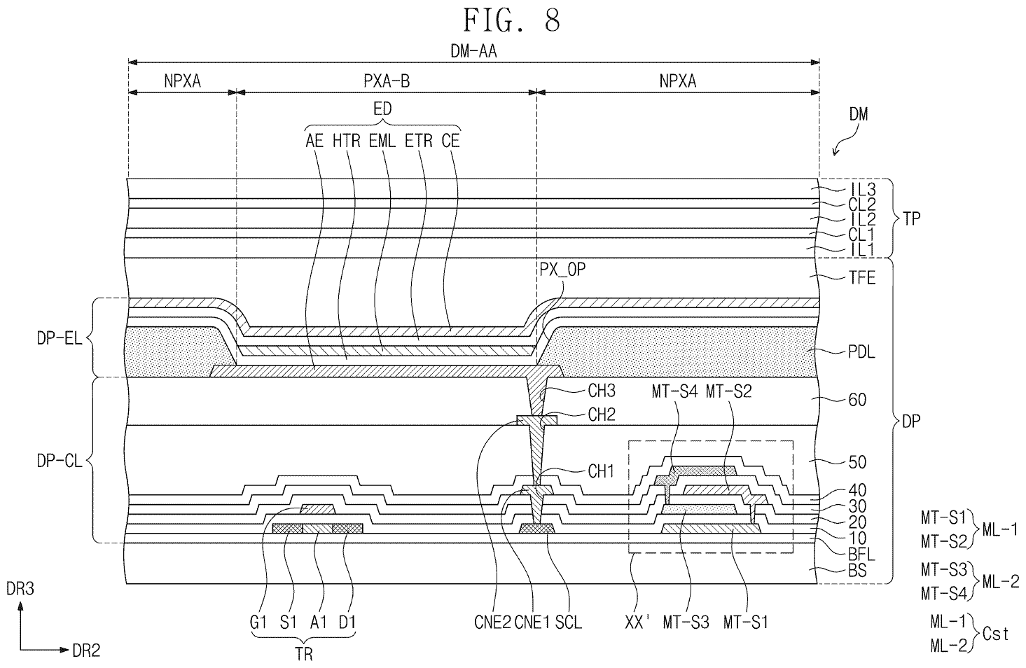

Referring to FIG. 2, the electronic apparatus EA may include a display device DD and a housing HAU. The electronic apparatus EA may further include a second electronic module ELM. The display device DD may include a display module DM and a window member CW disposed on the display module DM. The display module DM may be accommodated in the housing HAU. A module area DM-MH may be defined in the display module DM, and the second electronic module ELM may be arranged to correspond to the module area DM-MH. Specifically, the module area DM-MH may be defined in a display panel DP (see FIG. 8) included by the display module DM. The display panel DP (see FIG. 8) will be described later in more detail.

In the electronic apparatus EA illustrated in FIGS. 1 and 2, the window member CW and the housing HAU may be coupled to constitute an outer appearance of the electronic apparatus EA. The housing HAU may be disposed on a lower side of the display module DM. The housing HAU may include a material having relatively high rigidity. For example, the housing HAU may include a plurality of frames and/or plates, each of which may include glass, plastic, or metal. The housing HAU may provide an accommodation space. The second electronic module ELM, the display module DM, and the like may be accommodated in the accommodation space and protected against external impact.

The display module DM may be activated in response to an electrical signal. The display module DM may be activated to display the image IM (see FIG. 1) on the display area DA (see FIG. 1) of the electronic apparatus EA. An active area DM-AA, a peripheral area DM-NAA, and the module area DM-MH may be defined in the display module DM.

The active area DM-AA may be an area that is activated in response to an electrical signal. A pixel may be disposed in the active area DM-AA. The pixel may include a transistor TR (see FIG. 8) and a light emitting element ED (see FIG. 8), described later. The peripheral area DM-NAA may be an area adjacent to at least one side of the active area DM-AA. A circuit, a line, or the like, for driving the active area DM-AA may be disposed in the peripheral area DM-NAA.

The module area DM-MH may correspond to the sub-area MH illustrated in FIG. 1. A light signal such as visible light or infrared light may travel to the module area DM-MH. The module area DM-MH may be disposed within the active area DM-AA. Alternatively, the module area DM-MH may be surrounded by the peripheral area DM-NAA or surrounded by the active area DM-AA and the peripheral area DM-NAA.

The second electronic module ELM may be an electronic component that outputs or receives the light signal. For example, the second electronic module ELM may include a camera module and a photosensor. The camera module may transduce an external image through the module area DM-MH. The photosensor may transduce light incident on the photosensor, and the incident light may be infrared light. The photosensor may receive infrared light reflected by an external object and sense approach of the external object. The photosensor may function as a proximity sensor.

Although not illustrated, the display device DD may further include an optical layer disposed between the display module DM and the window member CW. The optical layer may be formed on the display module DM through a continuous process. The optical layer may include a polarizing plate or include a color filter layer. For example, the optical layer may include at least one of a retarder, a polarizer, a polarizing film, or a polarizing filter. Alternatively, the optical layer may include a plurality of color filters arranged in a certain arrangement. For example, the color filters may be arranged considering emissive colors of pixels. In addition, the optical layer may further include a black matrix adjacent to the color filters.

The window member CW may include a transmission area TA and a bezel area BZA. The transmission area TA may overlap at least a portion of the active area DM-AA of the display module DM. The transmission area TA may be an optically transparent area. The image IM (see FIG. 1) may be provided for a user through the transmission area TA.

The bezel area BZA may be an area having a relatively low light transmittance compared to the transmission area TA. The bezel area BZA may define a shape of the transmission area TA. The bezel area BZA may be adjacent to the transmission area TA and surround the transmission area TA.

The bezel area BZA may have a certain color. The bezel area BZA may cover the peripheral area DM-NAA of the display module DM to prevent the peripheral area DM-NAA from being visible from the outside. However, an embodiment is not limited to the illustrated embodiment, and the bezel area BZA may be disposed adjacent to only one side of the transmission area TA, or may have at least a portion thereof omitted.

Referring to FIG. 3, an electronic apparatus EA according to an embodiment may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The power module 14 may include a power supply module such as a power adapter or a battery device, and a power conversion module which converts the power supplied by the power supply module to a useable form and provides the form of power (operating wattage, voltage, amperage, phase, etc.) necessary for an operation of the electronic apparatus EA.

The memory 13 may store data information necessary for an operation of the processor 12 or the display module DM. When the processor 12 executes an application stored in the memory 13, transmits, an image data signal and/or an input control signal may be transmitted to the display module DM, and the display module DM may process the received signal and output image information through a display screen.

In some implementations, at least one of the components of the electronic apparatus EA may be included in the display device DD (see FIG. 2). In addition, among the components of the electronic apparatus EA, some of individual modules included as functional in one module may be included in the display device DD (see FIG. 2), and others may be provided separately from the display device DD (see FIG. 2). For example and without limitation, the display device DD (see FIG. 2) may include the display module DM, and the processor 12, the memory 13. The power module 14 may be provided not in the display device DD (see FIG. 2) but in another type of device in the electronic apparatus EA.

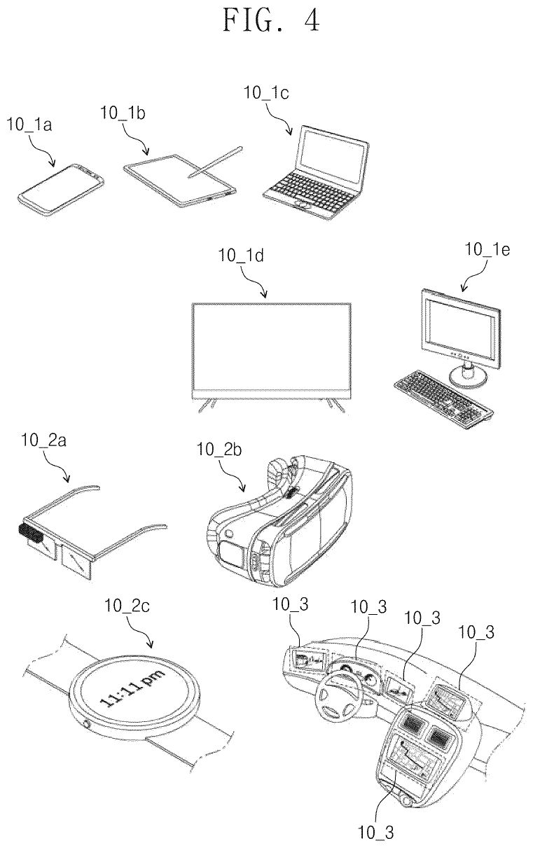

FIG. 4 is a schematic view illustrating electronic apparatuses according to aspects of the present disclosure. Referring to FIG. 4, an electronic apparatus including the display device DD (see FIG. 2) may include not only an electronic apparatus for displaying an image, e.g., a smartphone 10_1a, a tablet computer (PC) 10_1b, a laptop computer 10_1c, TV 10_1d, and a monitor for a desk computer 10_1e, but also a wearable electronic apparatus including the display module DM (see FIG. 3), e.g., smart glasses 10_2a, a head mounted display 10_2b, and a smart watch 10_2c, and a vehicle electronic apparatus 10_3 including the display module DM (see FIG. 3), e.g., a vehicle instrument panel, a center fascia, a center information display (CID) disposed on a dashboard, and a room mirror display.

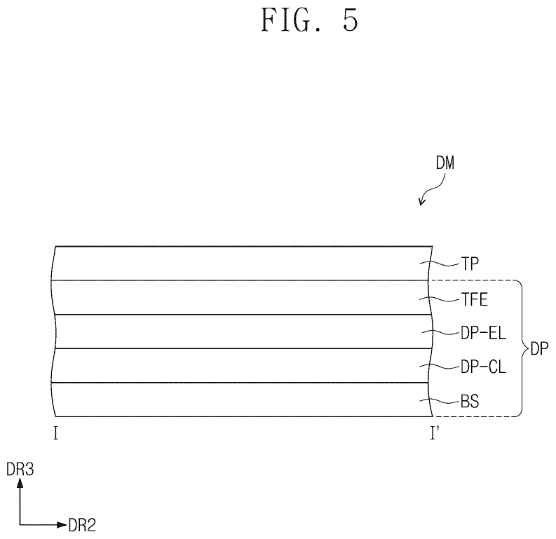

FIG. 5 is a cross-sectional view illustrating a portion corresponding to line I-I′ in FIG. 2. FIG. 5 may be a schematic cross-sectional view illustrating components of a display module DM.

Referring to FIG. 5, the display module DM may include a display panel DP and an input sensing part TP disposed on the display panel DP. The display panel DP may be a component that substantially generates an image.

The display panel DP may include a stack of a base layer BS, a circuit layer DP-CL, a display element layer DP-EL, and an encapsulation layer TFE. Not shown in the illustrated embodiment, a separate member layer may be further disposed between two adjacent layers among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate capable of bending, folding, rolling or the like. The base layer BS may be a glass substrate, a metal substrate, a polymer substrate, or the like. However, implementations are not limited thereto, and the base layer BS may include an inorganic layer, an organic layer, or a composite material layer.

The circuit layer DP-CL may be disposed on the base layer BS. The circuit layer DP-CL may include an insulating layer, a semiconductor pattern, a conductive pattern, a signal line, and the like. The display element layer DP-EL may be disposed on the circuit layer DP-CL. The display element layer DP-EL may include a light emitting element ED (see FIG. 8) to be described later. For example, the light emitting element ED (see FIG. 8) may include an organic light emitting material, an inorganic light emitting material, an organic-inorganic light emitting material, a quantum dot, a quantum rod, or the like. For example, the light emitting element ED (see FIG. 8) may include a micro LED or a nano LED.

The encapsulation layer TFE may be disposed on the display element layer DP-EL. The encapsulation layer TFE may protect the display element layer DP-EL from moisture, oxygen, and foreign matter such as dust particles. The encapsulation layer TFE may include at least one inorganic layer. For example, the encapsulation layer TFE may include an inorganic layer, organic layer, inorganic layer stack.

The input sensing part TP may be disposed on the display panel DP. The input sensing part TP may be directly disposed on the encapsulation layer TFE. Alternatively, an adhesive member may be disposed between the input sensing part TP and the display panel DP.

In the present disclosure, when one component is referred to as being directly disposed/provided/formed on another component, it means that a third component is not disposed/provided/formed between the one component and the other component. That is, when one component is referred to as being “directly disposed/provided/formed” on another component, it means that the one component and the other component are in “contact” with each other.

The input sensing part TP may sense an external input to covert the external input into an input signal and provide the input signal to the display panel DP. For example, the input sensing part TP may be a touch sensing layer that senses a touch. The input sensing part TP may transduce a direct touch by a user, an indirect touch by a user, a direct touch by an object, an indirect touch by an object, or the like into the input signal.

The input sensing part TP may sense at least one of a position of a touch applied from the outside, or an intensity (pressure) of the touch. In an embodiment, the input sensing part TP may have various structures or include various materials, and is not limited to any one embodiment. For example, the input sensing part TP may sense an external0 input by using a capacitance method. The display panel DP may receive an input signal from the input sensing part TP, and generate an image corresponding to the input signal.

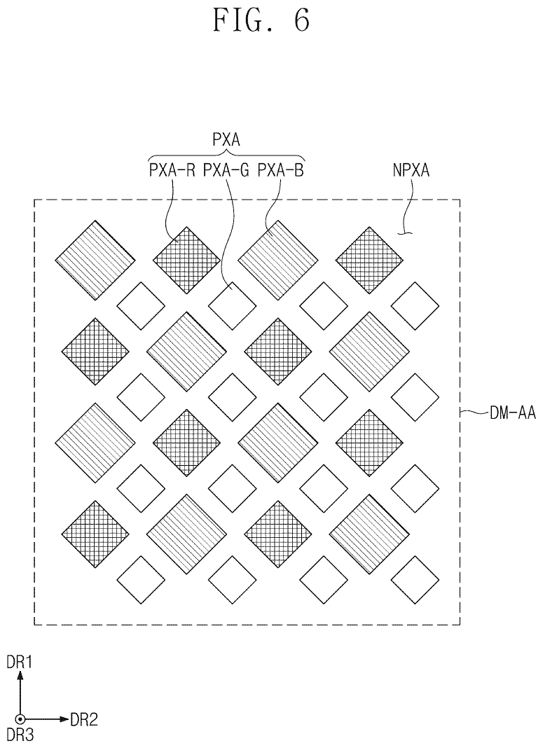

FIG. 6 is an enlarged plan view illustrating a portion of an active area according to an embodiment. Referring to FIG. 6, an active area DM-AA may include a light emitting area PXA and a light blocking area NPXA. The light blocking area NPXA may surround the light emitting area PXA.

The light emitting area PXA may be provided as a plurality of light emitting areas which are configured to emit light in different wavelength regions. The light emitting area PXA may include a first light emitting area PXA-B, a second light emitting area PXA-G, and a third light emitting area PXA-R. For example, the first light emitting area PXA-B may be configured to emit blue light, the second light emitting area PXA-G may be configured to emit green light, and the third light emitting area PXA-R may be configured to emit red light. However, an embodiment is not limited thereto, and the first to third light emitting areas PXA-B, PXA-G and PXA-R may be configured to emit light of colors other than the blue light, the green light, and the red light.

Among the light emitting areas PXA, the first light emitting area PXA-B which is configured to emit blue light may have the largest surface area, and the second light emitting area PXA-G which is configured to emit green light may have the smallest surface area. Here, the surface area indicates a surface area on a plane. However, this is illustrative, and the surface areas of the first to third light emitting areas PXA-B, PXA-G and PXA-R are not limited thereto.

As illustrated in FIG. 6, the first light emitting area PXA-B and the third light emitting area PXA-R are arranged in alternating order in a first row along the second direction DR2. The second light emitting area PXA-G is arranged in a second row to spaced apart from first row created by the first light emitting area PXA-B and the third light emitting area PXA-R. However, this is illustrative, and the arrangement of the first to third light emitting areas PXA-B, PXA-G and PXA-R is not limited thereto. In addition, the respective shapes of the first to third light emitting areas PXA-B, PXA-G and PXA-R on a plane are not limited to the illustrated shapes, and may be defined as different shapes from the illustrated shapes.

The light blocking area NPXA may be an area between neighboring light emitting areas among the light emitting areas PXA-B, PXA-G and PXA-R, and an area corresponding to a pixel defining film PDL (see FIG. 8) to be described later. The light emitting area PXA may be an area corresponding to a light emitting element ED (see FIG. 8) to be described later.

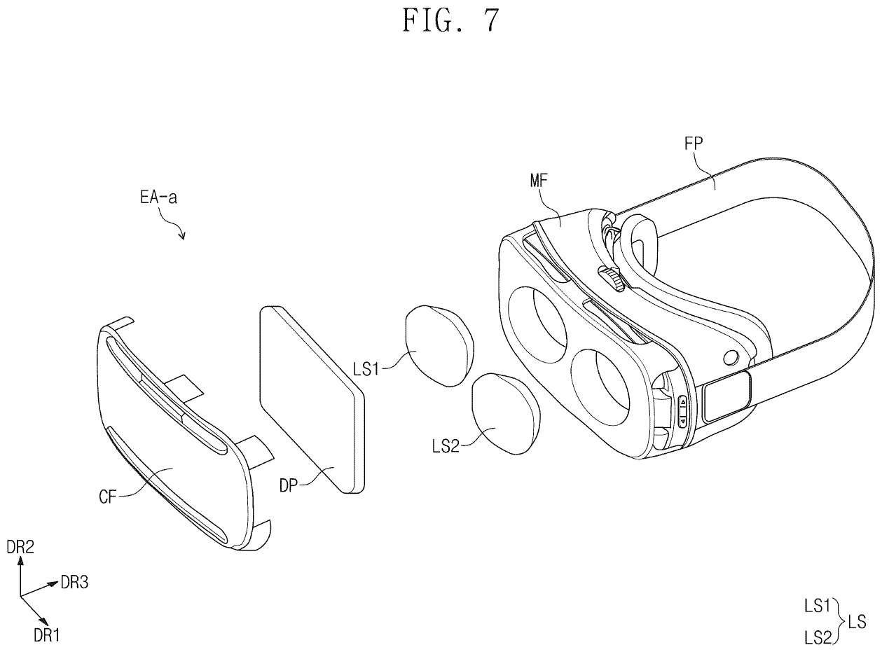

FIG. 7 is an exploded perspective view illustrating an electronic apparatus according to aspects of the present disclosure. FIG. 7 illustrates a head mounted display (HMD) apparatus as one example of an electronic apparatus EA-a. The head mounted display apparatus may be an apparatus which is mounted on a user's head and provides the user with a screen on which a video or an image is displayed. The head mounted display apparatus may include a see-through type which provides augmented reality (AR) on the basis of real external objects, and a see-closed type which provides virtual reality (VR) for a user on a screen independent of an external object.

The electronic apparatus EA-a may include a display panel DP and a lens part LS facing the display panel DP. In addition, the electronic apparatus EA-a may include a main frame MF, a cover frame CF, and a fixing part FP.

The main frame MF may be a portion worn on the user's face. The main frame MF may have a shape corresponding to a shape of the user's head (face). For example, a length of the fixing part FP may be adjusted according to a head circumference of the user. The fixing part FP may include a strap, a band, or the like as a structure that allows the main frame MF to be easily mounted. However, an embodiment is not limited thereto, and the fixing part FP may be in the form of, for example, a helmet or glasses temple which is coupled to the main frame MF.

The lens part LS, the display panel DP, and the cover frame CF may be mounted on the main frame MF. The main frame MF may include a space or structure in which the lens part LS and the display panel DP may be accommodated.

The lens part LS may be disposed between the display panel DP and the user. The lens part LS may transmit light emitted from the display panel DP and provide the light for the user. For example, the lens part LS may include various types of lenses such as multi-channel lens, convex lens, concave lens, spherical lens, aspherical lens, single lens, compound lens, standard lens, narrow-angle lens, wide-angle lens, fixed focus lens, and varifocal lens.

The lens part LS may include a first lens LS1 and a second lens LS2. The first lens LS1 and the second lens LS2 may be respectively arranged to correspond to positions of a left eye and a right eye of the user. The first lens LS1 and the second lens LS2 may be accommodated inside the main frame MF.

The display panel DP may be fixed to the main frame MF, or alternatively, may be detachable from the main frame MF. Hereinafter, the various implementations and aspects of the display panel DP as discussed throughout this disclosure may apply to the display panel DP illustrated in FIGS. 5 and 7.

The cover frame CF may be disposed on one surface of the display panel DP and protect the display panel DP. The cover frame CF and the lens part LS may be spaced apart from each other with the display panel DP disposed between the cover frame CF and the lens part LS.

FIG. 8 is a cross-sectional view specifically illustrating an active area DM-AA of a display module DM according to aspects of the present disclosure. FIG. 8 may be further understood as a cross-sectional view illustrating a portion corresponding to the first light emitting area PXA-B and the light blocking area NPXA adjacent to the first light emitting area PXA-B, as illustrated in FIG. 6. While the features are herein discussed as applied to the first light emitting area PXA-B, it should be understood that said features may also apply to the second and third light emitting areas PXA-G and PXA-R illustrated in FIG. 6.

Referring to FIG. 8, a base layer BS may include a single layer or a plurality of layers. For example and without limitation, the base layer BS may include a first synthetic resin layer, an inorganic layer having a multilayer or single-layer structure, and a second synthetic resin layer disposed on the inorganic layer having the multilayer or single-layer structure. The first synthetic resin layer and the second synthetic resin layer may each include a polyimide-based resin. In addition, the first synthetic resin layer and the second synthetic resin layer may each include at least one of acryl-based resin, methacryl-based resin, polyisoprene-based resin, vinyl-based resin, epoxy-based resin, urethane-based resin, cellulose-based resin, siloxane-based resin, polyamide-based resin, or perylene-based resin. The term “α-based” resin used herein indicates one including a functional group of “α”.

A display panel DP may include a transistor TR, a light emitting element ED, and a capacitor Cst. The transistor TR, the light emitting element ED, and the capacitor Cst may be disposed on the base layer BS. Although FIG. 8 illustrates one transistor TR, the display panel DP may include a plurality of transistors for driving the light emitting element ED. In addition, not shown in the illustrated embodiment, the display panel DP may include a plurality of capacitors Cst.

A circuit layer DP-CL may include an insulating layer, a semiconductor pattern, a conductive pattern, a signal line, and the like. For example, the circuit layer DP-CL may include a switching transistor and a driving transistor for driving the light emitting element ED of a display element layer DP-EL.

The circuit layer DP-CL may include a plurality of insulating layers BFL and 10 to 60. The plurality of insulating layers BFL and 10 to 60 may include a buffer layer BFL and first to sixth insulating layers 10 to 60.

The buffer layer BFL may be disposed on the base layer BS. The buffer layer BFL may include an inorganic layer. The buffer layer BFL may improve bonding force between the base layer BS and the semiconductor pattern (or the conductive pattern) disposed on the buffer layer BFL.

Semiconductor patterns S1, A1, D1 and SCL may be disposed on the buffer layer BFL. The semiconductor patterns S1, A1, D1 and SCL may be an oxide semiconductor pattern. However, this is illustrative, and in the display panel DP, the semiconductor pattern may include amorphous silicon, low temperature polycrystalline silicon, and/or a polysilicon.

FIG. 8 just illustrates a portion of the semiconductor patterns S1, A1, D1 and SCL, and a semiconductor pattern may be further disposed in other areas. The semiconductor patterns S1, A1, D1 and SCL may be arranged over the active area DM-AA (see FIG. 2). The semiconductor patterns S1, A1, D1 and SCL may have different electrical properties according to whether the semiconductor patterns S1, A1, D1 and SCL are doped or not. The semiconductor patterns S1, A1, D1 and SCL may include first regions S1, D1 and SCL having high conductivity and a second region A1 having low conductivity. The first regions S1, D1 and SCL may be doped with an n-type dopant or a p-type dopant. A p-type transistor may include a doped region doped with the p-type dopant, and an n-type transistor may include a doped region doped with the n-type dopant. The second region A1 may be a non-doped region, or a region doped at a lower concentration than each of the first regions S1, D1 and SCL. The display panel DP according to an embodiment may include a n-type transistor.

Each of the first regions S1, D1 and SCL may have a higher conductivity than the conductivity of the second region A1, and substantially serve as an electrode or a signal line. The second region A1, may substantially correspond to a channel A1 (or an active) of the transistor TR. That is, the second region A1 of the semiconductor patterns S1, A1, D1 and SCL may be the channel A1 of the transistor TR, other portions (S1 and D1) thereof may be a source S1 or a drain D1 of the transistor TR, and still another portion (SCL) thereof may be a connection electrode or a connection signal line SCL.

The source S1, the channel A1, and the drain D1 of the transistor TR may be provided from the semiconductor patterns S1, A1, D1 and SCL. The source S1 and the drain D1 may extend from the channel A1 in opposite directions on a cross-section. FIG. 8 illustrates a portion of the connection signal line SCL provided from the semiconductor patterns S1, A1, D1 and SCL. Although not illustrated, the connection signal line SCL may be electrically connected to the drain D1 of the transistor TR on a plane.

The capacitor Cst may be disposed on the buffer layer BFL. In an embodiment, the capacitor Cst may include a first metal layer ML-1 and a second metal layer ML-2. The first metal layer ML-1 and the second metal layer ML-2 may each include a conductive metal.

The first metal layer ML-1 may include a first sub-metal layer MT-S1, and a second sub-metal layer MT-S2 partially disposed on the first sub-metal layer MT-S1. The second metal layer ML-2 may include a third sub-metal layer MT-S3, and a fourth sub-metal layer MT-S4 partially disposed on the third sub-metal layer MT-S3. The first to fourth sub-metal layers MT-S1, MT-S2, MT-S3 and MT-S4 may be comprised from the type of same metal, or at least one thereof may include a different type of metal.

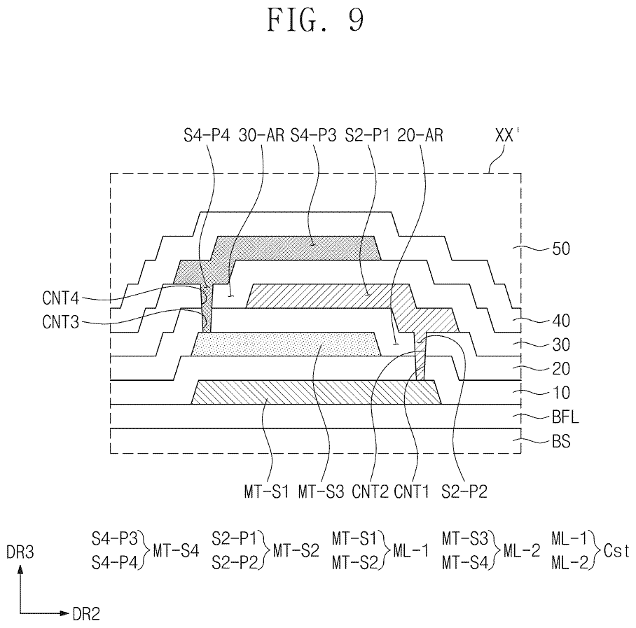

The first sub-metal layer MT-S1 may be disposed on a different layer from the third sub-metal layer MT-S3. At least a portion of the second sub-metal layer MT-S2 may be disposed on a different layer from the fourth sub-metal layer MT-S4. A first portion S2-P1 (see FIG. 9) of the second sub-metal layer MT-S2, described later, may be disposed on a different layer from a third portion S4-P3 (see FIG. 9) of the fourth sub-metal layer MT-S4, described later.

For example, each of the first to fourth sub-metal layers MT-S1, MT-S2, MT-S3 and MT-S4 may be directly disposed on any one insulating layer. The first sub-metal layer MT-S1 may be directly disposed on the buffer layer BFL. The third sub-metal layer MT-S3 may be directly disposed on the first insulating layer 10. A portion of the second sub-metal layer MT-S2 may be directly disposed on the second insulating layer 20. A portion of the fourth sub-metal layer MT-S4 may be directly disposed on the third insulating layer 30. However, this is illustrative, and the insulating layers on which the first to fourth sub-metal layers MT-S1, MT-S2, MT-S3 and MT-S4 are directly disposed may be changed according to a stack structure of the circuit layer DP-CL.

The first insulating layer 10 may be disposed on the buffer layer BFL. The first insulating layer 10 may cover the semiconductor patterns S1, A1, D1 and SCL and the first sub-metal layer MT-S1 of the capacitor Cst. In addition, the first insulating layer 10 may cover at least a portion of the connection signal line SCL. The first insulating layer 10 may be provided as a common layer running through the first light emitting area PXA-B and the light blocking area NPXA.

A gate G1 of the transistor TR may be disposed on the first insulating layer 10. The gate G1 may be a portion of a metal pattern. The gate G1 may overlap the channel A1. The gate G1 may function as a mask in a process of doping or reducing the semiconductor patterns S1, A1, D1 and SCL.

The second insulating layer 20 may be disposed on the first insulating layer 10, and cover the gate G1 of the transistor TR and the third sub-metal layer MT-S3 of the capacitor Cst. The second insulating layer 20 may be provided as a common layer running through the first light emitting area PXA-B and the light blocking area NPXA.

The third insulating layer 30 may be disposed on the second insulating layer 20, and cover the second sub-metal layer MT-S2 of the capacitor Cst. A first connection electrode CNE1 may be disposed on the third insulating layer 30. The first connection electrode CNE1 may be connected to the connection signal line SCL through a first contact hole CH1 passing through the first to third insulating layers 10, 20 and 30.

The fourth insulating layer 40 may be disposed on the third insulating layer 30. The fourth insulating layer 40 may cover the first connection electrode CNE1 and the fourth sub-metal layer MT-S4 of the capacitor Cst.

The fifth insulating layer 50 may be disposed on the fourth insulating layer 40. A second connection electrode CNE2 may be disposed on the fifth insulating layer 50. The second connection electrode CNE2 may be connected to the first connection electrode CNE1 through a second contact hole CH2 passing through the fourth insulating layer 40 and the fifth insulating layer 50. The sixth insulating layer 60 may be disposed on the fifth insulating layer 50 and cover the second connection electrode CNE2. The sixth insulating layer 60 may be a planarization layer.

Each of the first to sixth insulating layers 10 to 60 may be an inorganic layer and/or an organic layer. The first to third insulating layers 10 to 30 may have a single-layer structure. Each of the fourth to sixth insulating layers 40 to 60 may include a single layer or a plurality of layers. For example and without limitation, an inorganic layer may include at least one of aluminum oxide, titanium oxide, silicon oxide, silicon oxynitride, zirconium oxide, or hafnium oxide. By way of example and not by way of limitation, an organic layer may include at least one of acryl-based resin, methacryl-based resin, polyisoprene-based resin, vinyl-based resin, epoxy-based resin, urethane-based resin, cellulose-based resin, siloxane-based resin, polyamide-based resin, or perylene-based resin. In an example implementation, each of the first to fourth insulating layers 10 to 40 may be an inorganic layer and each of the fifth and sixth insulating layers 50 and 60 may be an organic layer.

The display element layer DP-EL may include a pixel defining film PDL and the light emitting element ED. The light emitting element ED may include a first electrode AE, a second electrode CE disposed over the first electrode AE, and an emission layer EML disposed between the first electrode AE and the second electrode CE. In addition, the light emitting element ED may further include a hole control layer HTR and an electron control layer ETR. The hole control layer HTR may be disposed between the first electrode AE and the emission layer EML. The electron control layer ETR may be disposed between the emission layer EML and the second electrode CE.

The light emitting element ED may be configured to emit light when provided with sufficient energy. For example, the light emitting element ED may include an organic light emitting material, an inorganic light emitting material, an organic-inorganic light emitting material, a quantum dot, or a quantum rod. For example, the light emitting element ED may include a micro LED or a nano LED.

The first electrode AE may be disposed on the sixth insulating layer 60. The first electrode AE may be connected to the second connection electrode CNE2 through a third contact hole CH3 passing through the sixth insulating layer 60 which may be filled by the material of the first electrode. The first electrode AE may be connected to the connection signal line SCL through the first and second connection electrodes CNE1 and CNE2. Although not illustrated, the first electrode AE may be electrically connected to the drain D1 of the transistor TR through the connection signal line SCL.

The first electrode AE may include a metal material, a metal alloy, or a conductive compound. The first electrode AE may be an anode or a cathode. However, aspects of the present disclosure should not be construed as limited thereto. The first electrode AE may be a pixel electrode. The first electrode AE may be a transmissive electrode, a semi-transmissive electrode, or a reflective electrode. The first electrode AE may include at least one material selected from Ag, Mg, Cu, Al, Pt, Pd, Au, Ni, Nd, Ir, Cr, Li, Ca, LiF, Mo, Ti, W, In, Sn, Zn, a compound of two or more selected therefrom, a mixture of two or more selected therefrom, or an oxide thereof.

In a case in which the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO) or the like. In a case in which the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). Alternatively, the first electrode AE may have a multilayer structure including a one or more reflective film or a semi-transmissive film, each of which may include the foregoing material, and one or more transmissive conductive film which may include indium tin oxide (ITO), indium zinc oxide (IZO), zinc oxide (ZnO), indium tin zinc oxide (ITZO) or the like. For example, the first electrode AE may have a three-layer structure of ITO/Ag/ITO, but is not limited thereto. However, implementations are not limited thereto, and the first electrode AE may include the foregoing metal material, a combination of two or more metal materials selected from the foregoing metal materials, an oxide of the foregoing metal materials, or the like.

The pixel defining film PDL may be disposed on the sixth insulating layer 60. An emission opening PX_OP around at least a portion of the first electrode AE may be defined in the pixel defining film PDL. The portion of the first electrode AE, which is located in the emission opening PX_OP of the pixel defining layer PDL, may be defined as the first light emitting area PXA-B.

The hole control layer HTR may be disposed on the first electrode AE and the pixel defining film PDL. The hole control layer HTR may be provided as a common layer overlapping the first light emitting area PXA-B and the light blocking area NPXA. Unlike the illustrated embodiment, the hole control layer HTR may be disposed in an area corresponding to the emission opening PX_OP. The hole control layer HTR may include at least one of a hole transport layer, a hole injection layer, or an electron blocking layer. The hole control layer HTR may include a general hole injection material and/or a general hole transport material.

The emission layer EML may be disposed on the hole control layer HCL. The emission layer EML may be disposed in an area corresponding to the emission opening PX_OP. Alternatively, the emission layer EML may be provided as a common layer overlapping the first light emitting area PXA-B and the light blocking area NPXA. The emission layer EML may include an organic light emitting material and/or an inorganic light emitting material. The emission layer EML may be configured to emit light of one color of red, green, and blue colors. The emission layer EML corresponding to the first light emitting area PXA-B may be configured to emit blue light. An emission layer corresponding to the second light emitting area PXA-G (see FIG. 6) may be configured to emit green light. An emission layer corresponding to the third light emitting area PXA-R (see FIG. 6) may be configured to emit red light.

The electron control layer ETR may be disposed on the emission layer EML. The electron control layer ETR may be provided as a common layer overlapping the first light emitting area PXA-B and the light blocking area NPXA. In some implementations alternative to the illustrated embodiment, the electron control layer ETR may be disposed in an area corresponding to the emission opening PX_OP. The electron control layer ETR may include at least one of an electron transport layer, an electron injection layer, or a hole blocking layer. The electron control layer ETR may include a general electron injection material and/or a general electron transport material.

The second electrode CE may be disposed on the electron control layer ETR. The second electrode CE may be provided as a common layer overlapping the first light emitting area PXA-B and the light blocking area NPXA. The second electrode CE may be a common electrode. The second electrode CE may be a cathode or an anode, but an embodiment is not limited thereto. For example, when the first electrode AE is an anode, the second electrode CE may be a cathode, and when the first electrode AE is a cathode, the second electrode CE may be an anode.

The second electrode CE may be a transmissive electrode, a semi-transmissive electrode, or a reflective electrode. In a case in which the second electrode CE is a transmissive electrode, the second electrode CE may include a transparent metal oxide, for example, indium tin oxide (ITO), indium zinc oxide (IZO), zinc oxide (ZnO), indium tin zinc oxide (ITZO), or the like.

In a case in which the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb or MgYb). Alternatively, the second electrode CE may have a multilayer structure including one or more reflective film or semi-transmissive film, each of which may include the foregoing material, and one or more transparent conductive film which may include indium tin oxide (ITO), indium zinc oxide (IZO), zinc oxide (ZnO), indium tin zinc oxide (ITZO) or the like. For example, the second electrode CE may include the foregoing metal material, a combination of two or more metal materials selected from the foregoing metal materials, an oxide of the foregoing metal materials, or the like.

An encapsulation layer TFE may be disposed on the display element layer DP-EL. The encapsulation layer TFE may be disposed on the second electrode CE and cover the light emitting element ED. The encapsulation layer TFE may protect the display element layer DP-EL from moisture, oxygen, and/or foreign matter such as dust particles. The encapsulation layer TFE may include a plurality of thin films.

The encapsulation layer TFE may include at least one inorganic film. For example, the encapsulation layer TFE may include inorganic films disposed on the second electrode CE, and an organic film disposed between the inorganic films. The inorganic films may protect the light emitting element ED from moisture/oxygen, and the organic film may protect the light emitting element ED from foreign matter such as dust particles.

An input sensing part TP may be disposed on the display panel DP. For example, the input sensing part TP may be directly disposed on the encapsulation layer TFE of the display panel DP. Alternatively, an adhesive member (not shown) may be disposed between the input sensing part TP and the display panel DP.

The input sensing part TP may include a first sensing insulating layer IL1, a second sensing insulating layer IL2, and a third sensing insulating layer IL3. The input sensing part TP may include at least one conductive layer disposed on the sensing insulating layers. The input sensing part TP may include a first conductive layer CL1 and a second conductive layer CL2.

The first sensing insulating layer IL1 may be disposed on the encapsulation layer TFE. The first sensing insulating layer IL1 may include at least one inorganic insulating layer. The first sensing insulating layer IL1 may be in contact with the encapsulation layer TFE. Alternatively, the first sensing insulating layer IL1 may be omitted, and in this case, the first conductive layer CL1 may be in contact with the encapsulation layer TFE.

The first conductive layer CL1 may be disposed on the first sensing insulating layer ILL. The first conductive layer CL1 may include a plurality of first conductive patterns. The plurality of first conductive patterns may be disposed on the first sensing insulating layer ILL. The second sensing insulating layer IL2 may be disposed over the first sensing insulating layer IL1 and cover at least a portion of the first conductive layer CL1.

The second conductive layer CL2 may be disposed on the second sensing insulating layer IL2. The second conductive layer CL2 may include a plurality of second conductive patterns. The plurality of second conductive patterns may be disposed on the second sensing insulating layer IL2. Although not illustrated, the plurality of second conductive patterns may be respectively connected to the plurality of first conductive patterns through contact holes defined in the second sensing insulating layer IL2.

Each of the plurality of first conductive patterns of the first conductive layer CL1 and the plurality of second conductive patterns of the second conductive layer CL2 may be arranged over a corresponding light blocking area NPXA. Each of the plurality of first conductive patterns of the first conductive layer CL1 and the plurality of second conductive patterns of the second conductive layer CL2 may be a mesh pattern.

The third sensing insulating layer IL3 may be disposed on the second sensing insulating layer IL2, and may cover the second conductive layer CL2. Each of the second sensing insulating layer IL2 and the third sensing insulating layer IL3 may include an inorganic insulating layer or an organic insulating layer.

The first conductive layer CL1 and the second conductive layer CL2 may each have a single-layer structure, or have a multilayer structure in which layers are stacked in the third direction DR3. The conductive layers CL1 and CL2 each having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowire, graphene, or the like.

The conductive layers CL1 and CL2 each having a multilayer structure may include metal layers. The metal layers may have, for example, a three-layer structure of titanium (Ti)/aluminum (A1)/titanium (Ti). Each of the conductive layers CL1 and CL2 having a multilayer structure may include at least one metal layer and at least one transparent conductive layer.

FIG. 9 is an enlarged cross-sectional view illustrating area XX′ in FIG. 8. FIG. 9 illustrates a capacitor Cst and first to fifth insulating layers 10 to 50 adjacent to the capacitor Cst according to an aspect of the present disclosure.

A first trench CNT1 passing through the first insulating layer 10 in the thickness direction DR3 may be defined in the first insulating layer 10. Second and third trenches CNT2 and CNT3 passing through the second insulating layer 20 in the thickness direction DR3 may be defined in the second insulating layer 20. A fourth trench CNT4 passing through the third insulating layer 30 in the thickness direction DR3 may be defined in the third insulating layer 30.

The second trench CNT2 and the third trench CNT3 may be spaced apart from each other in the second direction DR2 perpendicular to the thickness direction DR3. The second trench CNT2 may overlap the first trench CNT1. The third trench CNT3 may overlap the fourth trench CNT4. A first inner side surface of the second insulating layer 20, which defines the second trench CNT2, may be aligned with an inner side surface of the first insulating layer 10, which defines the first trench CNT1. A second inner side surface of the second insulating layer 20, which defines the third trench CNT3, may be aligned with an inner side surface of the third insulating layer 30, which defines the fourth trench CNT4.

The first and second trenches CNT1 and CNT2 may be aligned over a first sub-metal layer MT-S1. The first and second trenches CNT1 and CNT2 may be configured such that they do not intersect the third sub-metal layer MT-S3. The third and fourth trenches CNT3 and CNT4 may be aligned over the third sub-metal layer MT-S3. The third and fourth trenches CNT3 and CNT4 may be configured such that they do not intersect a second sub-metal layer MT-S2.

The second sub-metal layer MT-S2 may include a first portion S2-P1, and a second portion S2-P2 extending from the first portion S2-P1. The first portion S2-P1 may be disposed on the second insulating layer 20. The first portion S2-P1 and the second portion S2-P2 may be continuous. The first insulating layer 10, the second insulating layer 20, and the third sub-metal layer MT-S3 are disposed between the first portion S2-P1 and the first sub-metal layer MT-S1 and separate the first portion S2-P1 of the second sub-metal layer MT-S2 from the first sub-metal later MT-S1 in the thickness direction.

The second portion S2-P2 of the second sub-metal layer MT-S2 may be disposed within the first and second trenches CNT1 and CNT2. The second portion S2-P2 of the second sub-metal layer MT-S2 may be fill the first and second trenches CNT1 and CNT2. The second portion S2-P2 of the second sub-metal layer MT-S2 may be disposed between the first sub-metal layer MT-S1 and the first portion S2-P1 of the second sub-metal layer MT-S2. The second portion S2-P2 of the second sub-metal layer MT-S2 may electrically connect the first sub-metal layer MT-S1 to the first portion S2-P1 of the second sub-metal layer MT-S2.

The fourth sub-metal layer MT-S4 may include a third portion S4-P3, and a fourth portion S4-P4 extending from the third portion S4-P3. The third portion S4-P3 may be disposed on the third insulating layer 30. The third portion S4-P3 and the fourth portion S4-P4 may be continuous. The second insulating layer 20, the third insulating layer 30, and the first portion S2-P1 of the second sub-metal layer MT-S2 are disposed between the third portion S4-P3 and the third sub-metal layer MT-S3 and separate the third portion S4-P3 of the fourth sub-metal layer MT-S4 from the third sub-metal later MT-S3 in the thickness direction.

The fourth portion S4-P4 of the fourth sub-metal layer MT-S4 may be disposed within the third and fourth trenches CNT3 and CNT4. The fourth portion S4-P4 of the fourth sub-metal layer MT-S4 may fill the third and fourth trenches CNT3 and CNT4. The fourth portion S4-P4 of the fourth sub-metal layer MT-S4 may be disposed between the third sub-metal layer MT-S3 and the third portion S4-P3 of the fourth sub-metal layer MT-S4. The fourth portion S4-P4 of the fourth sub-metal layer MT-S4 may electrically connect the third sub-metal layer MT-S3 to the third portion S4-P3 of the fourth sub-metal layer MT-S4.

At least one of the first insulating layer 10, the second insulating layer 20, or the third insulating layer 30 may have a single-layer structure. The single-layer structure may be in contact with two sub-metal layers adjacent to the insulating layer. The insulating layer having a single-layer structure may include silicon nitride. For example and without limitation the first insulating layer 10 may have a single-layer structure, and may be directly disposed between the first sub-metal layer MT-S1 and the third sub-metal layer MT-S3. The second insulating layer 20 may have a single-layer structure, and may be directly disposed between the third sub-metal layer MT-S3 and the first portion S2-P1 of the second sub-metal layer MT-S2. The third insulating layer 30 may have a single-layer structure, and may be directly disposed between the first portion S2-P1 of the second sub-metal layer MT-S2 and the third portion S4-P3 of the fourth sub-metal layer MT-S4. The first sub-metal layer MT-S1, the first portion S2-P1 of the second sub-metal layer MT-S2, the third sub-metal layer MT-S3, and the third portion S4-P3 of the fourth sub-metal layer MT-S4 may overlap each other.

In the second direction DR2 perpendicular to the thickness direction DR3, the fourth portion S4-P4 of the fourth sub-metal layer MT-S4 may be separated from the first portion S2-P1 of the second sub-metal layer MT-S2 with area 30-AR of the third insulating layer 30 disposed between the fourth portion S4-P4 and the first portion S2-P1. In the second direction DR2, the third sub-metal layer MT-S3 may be separated from the second portion S2-P2 of the second sub-metal layer MT-S2 with area 20-AR of the second insulating layer 20 disposed between the third sub-metal layer MT-S3 and the second portion S2-P2.

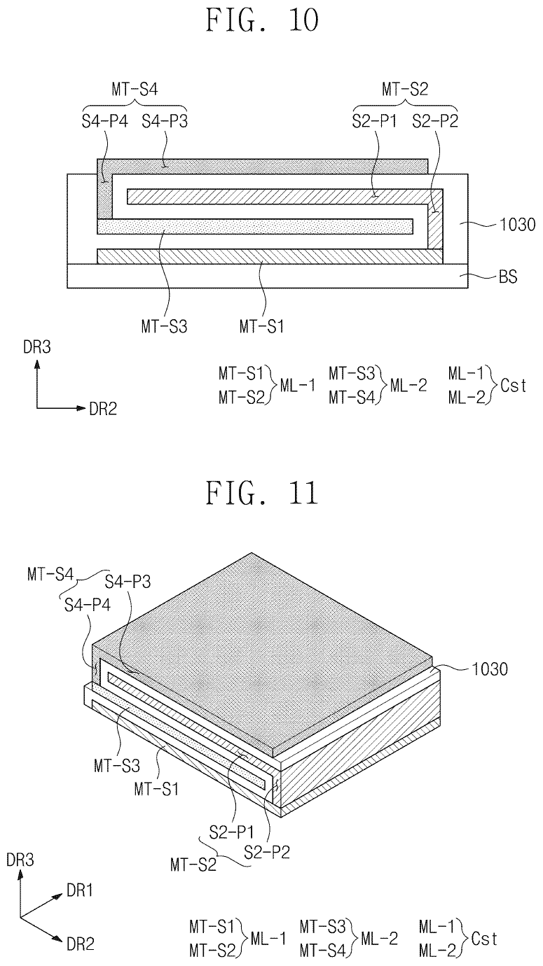

FIG. 10 is a schematic cross-sectional view illustrating a capacitor Cst according to an aspect of the present disclosure. For convenience of explanation, FIG. 10 schematically illustrates the capacitor Cst and components (i.e., a base layer BS and an insulating layer 1030) adjacent to the capacitor Cst, and does not illustrate some components. The insulating layer 1030 illustrated in FIG. 10 corresponds to the first to third insulating layers 10, 20 and 30 described with reference to FIGS. 8 and 9, and is schematically illustrated for convenience of explanation.

The capacitor Cst including first and second metal layers ML-1 and ML-2 may have a folded shape when viewed in cross-section. Each of the first and second metal layers ML-1 and ML-2 may have a folded shape, and the folded shape may include three non-folding portions and two folding portions. The three non-folding portions may be spaced apart from each other with the folding portions each disposed between the non-folding portions. Among the three non-folding portions, one non-folding portion may be provided having a relatively small surface area. The first metal layer ML-1 may have a closed square bracket shape (i.e., a “]” shape) in cross-section. The second metal layer ML-2 may have an open square bracket shape (i.e., a “[” shape) in cross-section. The closed square bracket shape and the open square bracket shape may each be a folded shape.

In the first metal layer ML-1, a first sub-metal layer MT-S1, a first portion S2-P1 of a second sub-metal layer MT-S2, and a second portion S2-P2 of the second sub-metal layer MT-S2 may correspond to the non-folding portions. A surface area of the second portion S2-P2 of the second sub-metal layer MT-S2 may be smaller than a surface area of each of the first sub-metal layer MT-S1 and the first portion S2-P1 of the second sub-metal layer MT-S2. The surface area indicates a surface area in a state in which the first sub-metal layer MT-S1, the first portion S2-P1 of the second sub-metal layer MT-S2, and the second portion S2-P2 of the second sub-metal layer MT-S2 are aligned with each other.

The first sub-metal layer MT-S1, the second portion S2-P2 of the second sub-metal layer MT-S2, and the first portion S2-P1 of the second sub-metal layer MT-S2 may have the closed square bracket shape in cross-section. The capacitor Cst may be configured such that the first portion S2-P1 of the second sub-metal layer MT-S2 is located between the third portion S4-P3 and the third metal layer MT-S3 of the closed square bracket shape. The first sub-metal layer MT-S1, the second portion S2-P2 of the second sub-metal layer MT-S2, and the first portion S2-P1 of the second sub-metal layer MT-S2 may comprise the folded shape.

In the second metal layer ML-2, a third sub-metal layer MT-S3, a third portion S4-P3 of a fourth sub-metal layer MT-S4, and a fourth portion S4-P4 of the fourth sub-metal layer MT-S4 may correspond to the non-folding portions. A surface area of the fourth portion S4-P4 of the fourth sub-metal layer MT-S4 may be smaller than a surface area of each of the third sub-metal layer MT-S3 and the third portion S4-P3 of the fourth sub-metal layer MT-S4. The surface area indicates a surface area in a state in which the third sub-metal layer MT-S3, the third portion S4-P3 of the fourth sub-metal layer MT-S4, and the fourth portion S4-P4 of the fourth sub-metal layer MT-S4 are aligned with each other.

On a cross-section, the third sub-metal layer MT-S3, the fourth portion S4-P4 of the fourth sub-metal layer MT-S4, and the third portion S4-P3 of the fourth sub-metal layer MT-S4 may have the open square bracket shape. The capacitor Cst may be configured such that the third sub-metal layer MT-S3 is located between the first sub-metal layer MT-S1 and the first portion S2-P1 of the open square bracket shape. On a cross-section, the third sub-metal layer MT-S3, the fourth portion S4-P4 of the fourth sub-metal layer MT-S4, and the third portion S4-P3 of the fourth sub-metal layer MT-S4 may comprise the folded shape.

FIG. 11 is a schematic perspective view illustrating a capacitor Cst according to an embodiment. FIG. 11 may be a schematic perspective view illustrating the capacitor Cst and the insulating layer 1030 in FIG. 10. Referring to FIG. 11, a third sub-metal layer MT-S3 may be located in between layers of the closed square bracket shape formed by the first and second sub-metal layers MT-S1 and MT-S2. A portion (i.e., the first portion S2-P1 illustrated in FIG. 10) of the second sub-metal layer MT-S2 may be located between layers of the open square bracket shape formed by third and fourth sub-metal layers MT-S3 and MT-S4.

FIG. 12 is a schematic perspective view illustrating an insulating layer 3010 in which a trench CNT is defined. The insulating layer 3010 illustrated in FIG. 12 may correspond to any of the first to third insulating layers 10, 20 and 30 described with reference to FIGS. 8 and 9, and is schematically illustrated for convenience of explanation. For convenience of explanation, FIG. 12 illustrates the insulating layer 3010 directly disposed on a base layer BS, but an embodiment is not limited thereto. Referring to FIG. 12, on a plane, the trench CNT may extend in the first direction DR1 perpendicular to the thickness direction DR3. The trench CNT illustrated in FIG. 12 may correspond to any of the first to fourth trenches CNT1 to CNT4 described with reference to FIG. 9.

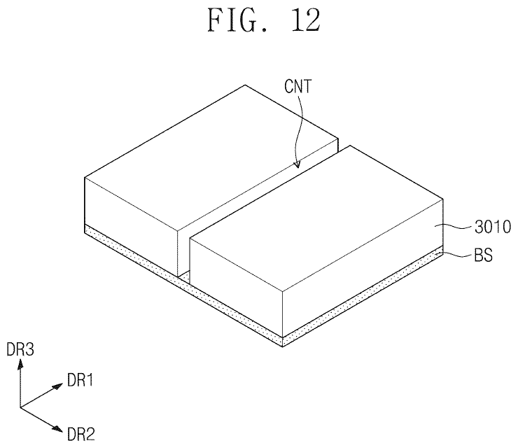

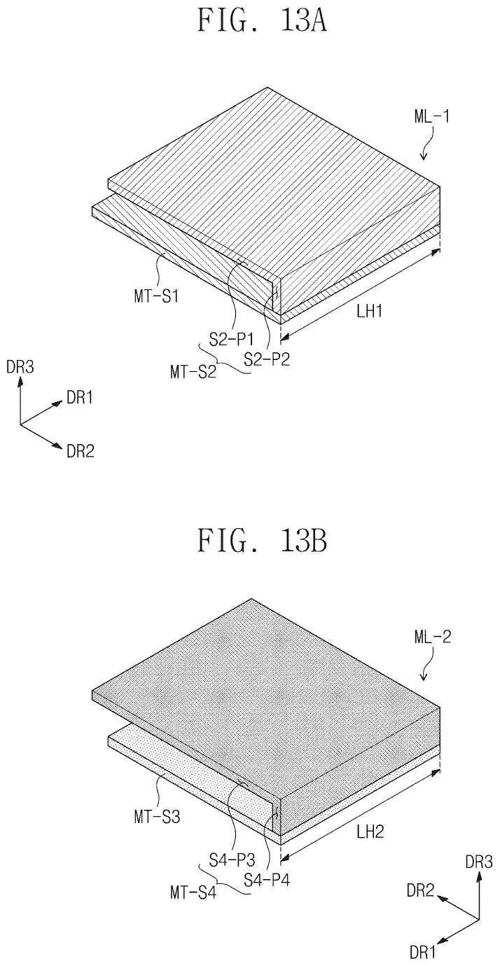

FIG. 13A is a perspective view illustrating the first metal layer ML-1 according to an embodiment. On a plane, a second portion S2-P2 of a second sub-metal layer MT-S2 may extend in the first direction DR1 perpendicular to the thickness direction DR3. The second portion S2-P2 of the second sub-metal layer MT-S2 may be disposed within the trench CNT (see FIG. 12) extending in the first direction DR1. In the first direction DR1, a length LH1 of the second portion S2-P2 may be substantially the same as a length of a first portion S2-P1. However, this is illustrative, and the length LH1 of the second portion S2-P2 may be different from the length of the first portion S2-P1. In the present disclosure, “being substantially the same” includes a case of being the same in terms of physical measurements, and a case of having a difference within a margin of error generated during a process.

FIG. 13B is a perspective view illustrating a second metal layer ML-2 according to an embodiment. On a plane, a fourth portion S4-P4 of a fourth sub-metal layer MT-S4 may extend in the first direction DR1 perpendicular to the thickness direction DR3. The fourth portion S4-P4 of the fourth sub-metal layer MT-S4 may be disposed within the trench CNT (see FIG. 12) extending in the first direction DR1. In the first direction DR1, a length LH2 of the fourth portion S4-P4 may be substantially the same as a length of a third portion S4-P3. However, this is illustrative, and the length LH2 of the fourth portion S4-P4 may be different from the length of the third portion S4-P3 in the first direction DR1.

In an embodiment, the first sub-metal layer MT-S1 (see FIGS. 11 and 13A), the first portion S2-P1 (see FIGS. 11 and 13A) of the second sub-metal layer MT-S2 (see FIGS. 11 and 13A), and the second portion S2-P2 (see FIGS. 11 and 13A) of the second sub-metal layer MT-S2 (see FIGS. 11 and 13A) may comprise the first metal layer ML-1 (see FIGS. 11 and 13A) of the capacitor Cst (see FIG. 11), and the first portion S2-P1 (see FIGS. 11 and 13A) of the second sub-metal layer MT-S2 (see FIGS. 11 and 13A) and the second portion S2-P2 (see FIGS. 11 and 13A) of the second sub-metal layer MT-S2 (see FIGS. 11 and 13A) may increase a surface area of the capacitor Cst (see FIG. 11). That is, the second portion S2-P2 (see FIGS. 11 and 13A) of the second sub-metal layer MT-S2 (see FIGS. 11 and 13A) may contribute to an increase in surface area of the capacitor Cst (see FIG. 11).

The third sub-metal layer MT-S3 (see FIGS. 11 and 13B), the third portion S4-P3 (see FIGS. 11 and 13B) of the fourth sub-metal layer MT-S4 (see FIGS. 11 and 13B), and the fourth portion S4-P4 (see FIGS. 11 and 13B) of the fourth sub-metal layer MT-S4 (see FIGS. 11 and 13B) may comprise the second metal layer ML-2 (see FIGS. 11 and 13B) of the capacitor Cst (see FIG. 11), and the third portion S4-P3 (see FIGS. 11 and 13B) of the fourth sub-metal layer MT-S4 (see FIGS. 11 and 13B) and the fourth portion S4-P4 (see FIGS. 11 and 13B) of the fourth sub-metal layer MT-S4 (see FIGS. 11 and 13B) may increase the surface area of the capacitor Cst. That is, the fourth portion S4-P4 (see FIGS. 11 and 13B) of the fourth sub-metal layer MT-S4 (see FIGS. 11 and 13B) may contribute to an increase in surface area of the capacitor Cst (see FIG. 11). That is, the capacitor Cst (see FIG. 11) according to an embodiment including the second portion S2-P2 (see FIGS. 11 and 13B) and the fourth portion S4-P4 (see FIGS. 11 and 13B) may have the maximized surface area. The capacitor Cst (see FIG. 11) including the folded shape may prevent foreign matter defects and also have the increased surface area to exhibit high-capacity characteristics. Thus, the display panel DP (see FIG. 8) including the capacitor Cst (see FIG. 11) according to an embodiment may have minimal parasitic capacitance and also exhibit excellent display quality. In addition, the display panel DP (see FIG. 8) including the capacitor Cst (see FIG. 11) according to an embodiment may exhibit excellent manufacturability.

A display panel adopted by an electronic apparatus, which provides virtual reality (VR), may implement an ultra-high resolution of about 1500 ppi (pixels per inch) or more. Ultra-high resolution display panel including an n-type transistor requires a capacitor having high-capacity characteristics. Parasitic capacitance may have a great influence on the ultra-high resolution display panel including the n-type transistor. In a case in which capacity of the capacitor is low, a display quality defect such as temporary image-sticking may be apparent in images generated by the display panel. In a case in which a thickness of an insulating layer is increased to increase the capacity of the capacitor, insulation properties are lost and the chances of foreign matter defects, such as particles embedding in the metal layer during the process of forming the metal layer of the capacitor, are significantly increased. The foreign matter such as particles is perceived as dark spots and causes a decrease in manufacturing efficiency.

Compared to a typical capacitor including first and second metal layers each having a single-layer structure, the capacitor Cst (see FIG. 11) according to an embodiment may be provided to have the increased surface area. The typical capacitor includes two metal layers, each of the two metal layers includes two sub-metal layers, and the two sub-metal layers in the one metal layer are electrically connected to each other through a contact hole. In a case in which the sub-metal layers are connected through the contact hole, a portion disposed in the contact hole does not contribute to an increase in surface area of the capacitor. The portion disposed in the contact hole has a very small surface area and cannot be considered the surface area of the capacitor.

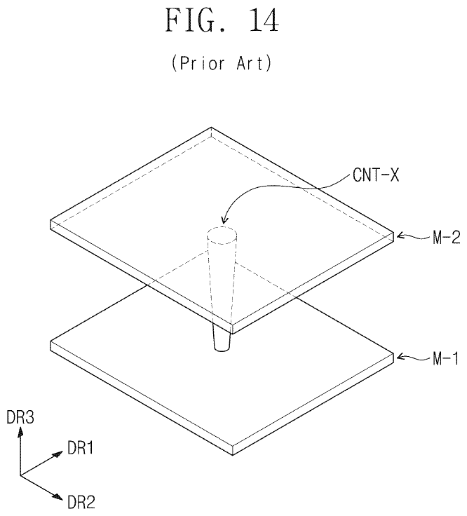

FIG. 14 is a schematic view illustrating a capacitor connected through a contact hole CNT-X. Referring to FIG. 14, two sub-metal layers M-1 and M-2 are connected to each other through the contact hole CNT-X, and the contact hole CNT-X has a very small surface area. Compared to the second portion S2-P2 of the second sub-metal layer MT-S2 or the fourth portion S4-P4 of the fourth sub-metal layer MT-S4 illustrated in FIGS. 11, 13A, and 13B, a portion disposed in the contact hole CNT-X illustrated in FIG. 14 has a very small surface area. Thus, the portion disposed in the contact hole CNT-X cannot be considered a surface area of the capacitor.

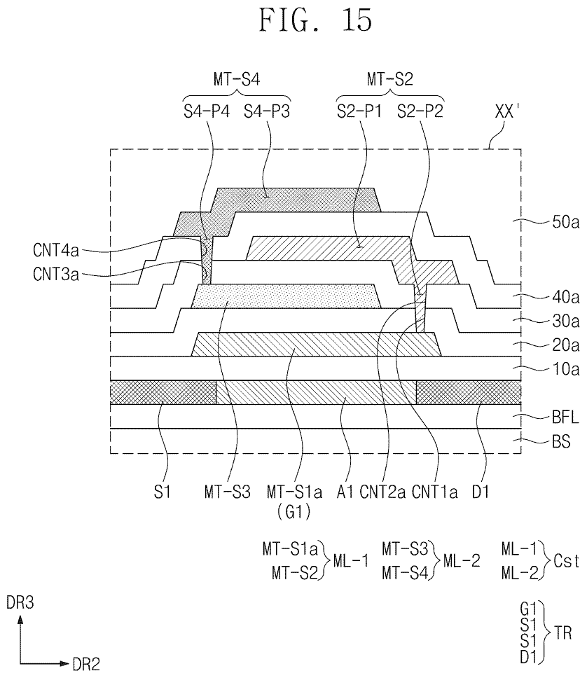

FIG. 15 is a cross-sectional view illustrating area XX′ according to an aspect of the present disclosure. Compared to FIG. 9, FIG. 15 is different in terms of a first sub-metal layer MT-Sla of a capacitor Cst. An embodiment will be described with reference to FIG. 15 by avoiding the contents in common with the contents described with reference to FIGS. 1 to 14, and mainly in terms of differences.

Referring to FIG. 15, a gate electrode G1 of a transistor TR may be a gate G1 and also part of the first sub-metal layer MT-Sla. At least a portion of the capacitor Cst may be arranged to overlap the transistor TR. A second sub-metal layer MT-S2, a third sub-metal layer MT-S3, and a fourth sub-metal layer MT-S4 of the capacitor Cst may overlap the transistor TR.

The gate electrode G1 may include a conductive metal. The gate electrode G1, a first portion S2-P1 of the second sub-metal layer MT-S2, the third sub-metal layer MT-S3, and a third portion S4-P3 of the fourth sub-metal layer MT-S4 may overlap each other.

The gate electrode G1 may be disposed on a first insulating layer 10a. A second insulating layer 20a may cover the gate electrode G1 and be disposed on the first insulating layer 10a. A third insulating layer 30a may cover the third sub-metal layer MT-S3 and be disposed on the second insulating layer 20a. A fourth insulating layer 40a may cover the second sub-metal layer MT-S2 and be disposed on the third insulating layer 30a. A fifth insulating layer 50a may cover the fourth sub-metal layer MT-S4 and be disposed on the fourth insulating layer 40a.

In FIG. 14 unlike FIG. 9, a first trench CNT1a may be defined in the second insulating layer 20a. The first trench CNT1a may pass through the second insulating layer 20a in the thickness direction DR3. Second and third trenches CNT2a and CNT3a may be defined in the third insulating layer 30a and spaced apart from each other in the second direction DR2 perpendicular to the thickness direction DR3. The second and third trenches CNT2a and CNT3a may pass through the third insulating layer 30a in the thickness direction DR3. A fourth trench CNT4a may be defined in the fourth insulating layer 40a. The fourth trench CNT4a may pass through the fourth insulating layer 40a in the thickness direction DR3.

The first trench CNT1a and the second trench CNT2a may be aligned over each other as shown. The third trench CNT3a and the fourth trench CNT4a may be aligned over each other. An inner side surface of the second insulating layer 20a, which defines the first trench CNT1a, may be aligned with a first inner side surface of the third insulating layer 30a, which defines the second trench CNT2a. A second inner side surface of the third insulating layer 30a, which defines the third trench CNT3a, may be aligned with an inner side surface of the fourth insulating layer 40a, which defines the fourth trench CNT4a.

A second portion S2-P2 of the second sub-metal layer MT-S2 may fill the first and second trenches CNT1a and CNT2a. A fourth portion S4-P4 of the fourth sub-metal layer MT-S4 may fill the third and fourth trenches CNT3a and CNT4a. In the second direction DR2 perpendicular to the thickness direction DR3, the third sub-metal layer MT-S3 and the second portion S2-P2 of the second sub-metal layer MT-S2 may be separated from each other with one area of the third insulating layer 30a disposed between the third sub-metal layer MT-S3 and the second portion S2-P2. In the second direction DR2 perpendicular to the thickness direction DR3, the fourth portion S4-P4 of the fourth sub-metal layer MT-S4 and the first portion S2-P1 of the second sub-metal layer MT-S2 may be separated from each other with one area of the fourth insulating layer 40a disposed between the fourth portion S4-P4 and the first portion S2-P1.

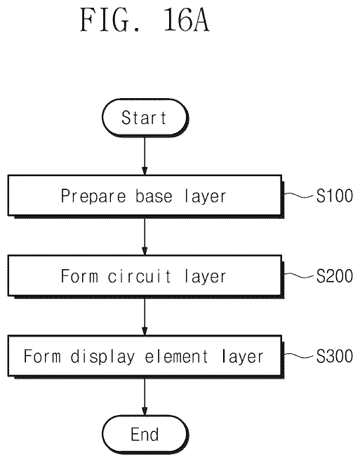

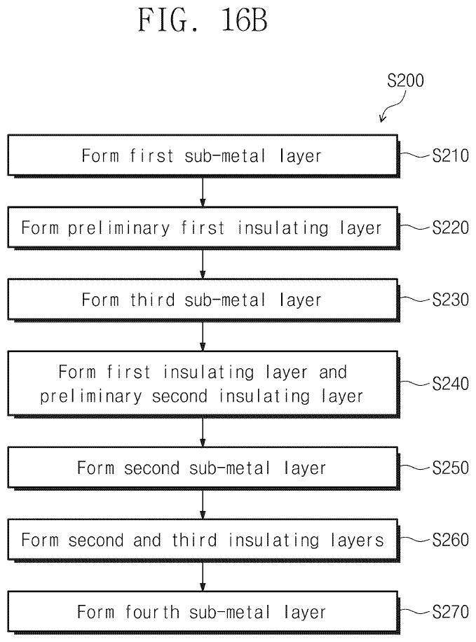

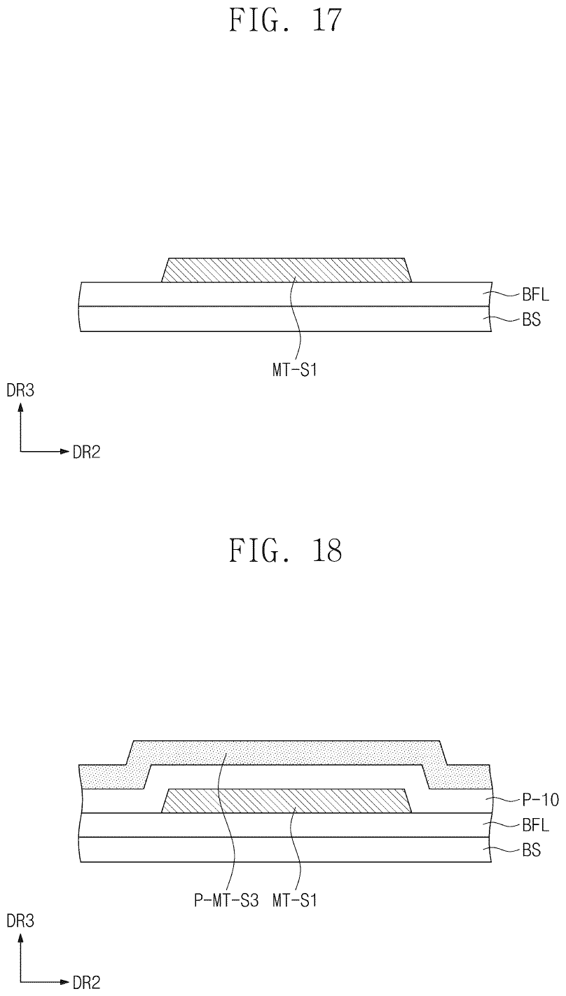

A display panel according to aspects of the present disclosure may be manufactured by a method for manufacturing a display panel as discussed herein. FIGS. 16A and 16B are each a flowchart illustrating a method for manufacturing a display panel according to aspects of the present disclosure. FIGS. 17 to 22 are each a schematic view illustrating a step of manufacturing a display panel according to an aspect of the present disclosure. Hereinafter, an embodiment will be described with reference to FIGS. 16A to 22 by avoiding the contents in common with the contents described with reference to FIGS. 1 to 15, and mainly in terms of differences.

Referring to FIG. 16A, the method for manufacturing the display panel according to an aspect of the present disclosure may include steps of preparing a base layer (S100), forming a circuit layer on the base layer (S200), and forming a display element layer on the circuit layer (S300). Referring to FIG. 16B, the step of forming the circuit layer (S200) may include steps of forming a first sub-metal layer (S210), forming a preliminary first insulating layer (S220), forming a third sub-metal layer (S230), forming a first insulating layer and a preliminary second insulating layer (S240), forming a second sub-metal layer (S250), forming second and third insulating layers (S260), and forming a fourth sub-metal layer (S270).

Referring to FIG. 17, a first sub-metal layer MT-S1 may be formed on a base layer BS. Specifically, the first sub-metal layer MT-S1 may be formed on a buffer layer BFL disposed on the base layer BS. For example and without limitation, a conductive metal may be deposited and patterned to form the first sub-metal layer MT-S1.

Referring to FIG. 18, a preliminary first insulating layer P-10 may be formed on the first sub-metal layer MT-S1. A preliminary third sub-metal layer P-MT-S3 may be formed on the preliminary first insulating layer P-10.

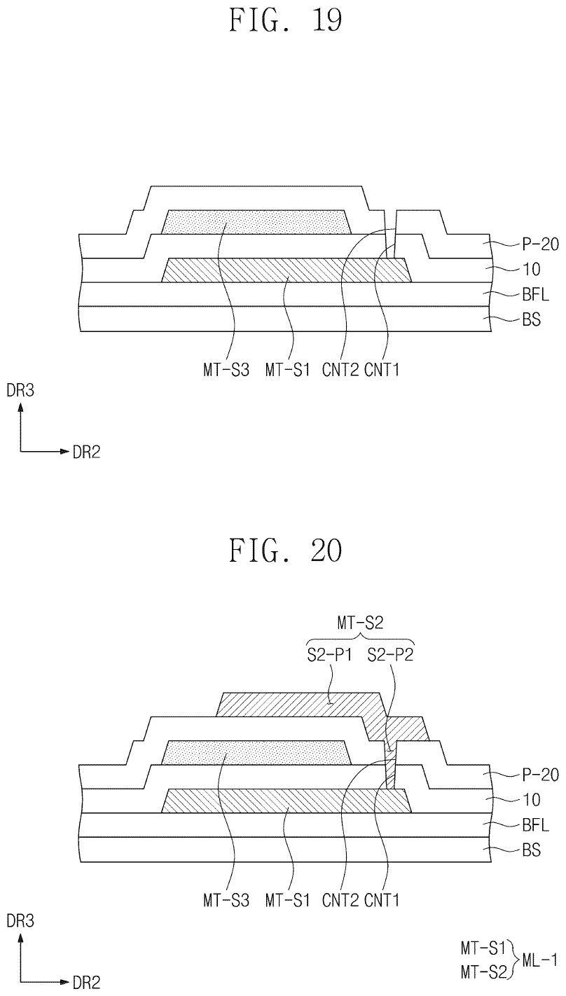

Then, as illustrated in FIG. 19, the preliminary third sub-metal layer P-MT-S3 may be patterned to form a third sub-metal layer MT-S3. A preliminary second insulating layer P-20 may be formed on the third sub-metal layer MT-S3. A second trench CNT2 may be formed in the preliminary second insulating layer P-20. The preliminary second insulating layer P-20 may cover the third sub-metal layer MT-S3.

A first insulating layer 10 may be formed from the preliminary first insulating layer P-10 (see FIG. 18). A first trench CNT1 may be formed in the preliminary first insulating layer P-10 (see FIG. 18) to form the first insulating layer 10. The first insulating layer 10 may cover the first sub-metal layer MT-S1.

The first and second trenches CNT1 and CNT2 may be formed in the same step to be aligned with each other. A material for forming the preliminary second insulating layer P-20 may be deposited onto the preliminary first insulating layer P-10 (see FIG. 18) covering the third sub-metal layer MT-S3, and after this deposition, the first and second trenches CNT1 and CNT2 may be formed together.

Then, as illustrated in FIG. 20, a second sub-metal layer MT-S2 may be formed on the preliminary second insulating layer P-20. The second sub-metal layer MT-S2 may fill the first and second trenches CNT1 and CNT2 during formation. The second portion S2-P2 of the second sub-metal layer MT-S2 formed from material of the second sub-metal layer located within the first and second trenches CNT1 and CNT2. A metal material may be deposited onto a second insulating layer 20, and the deposited metal material may be patterned to form a first portion S2-P1 of the second sub-metal layer MT-S2.

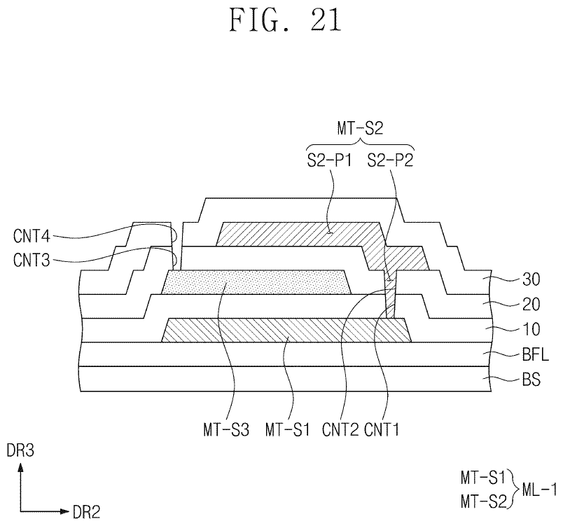

Then, as illustrated in FIG. 21, the second insulating layer 20 may be formed from the preliminary second insulating layer P-20 (see FIG. 20). A third trench CNT3 may be formed in the preliminary second insulating layer P-20 (see FIG. 20) in which the second trench CNT2 is formed, thereby forming the second insulating layer 20. This may be performed with the creation of the fourth trench CNT4 as discussed below. The second trench CNT2 and the third trench CNT3 may be spaced apart from each other in the second direction DR2.

A third insulating layer 30 may be formed on the second sub-metal layer MT-S2. The third insulating layer 30 may cover the second sub-metal layer MT-S2. A fourth trench CNT4 may be formed in the third insulating layer 30. In some implementations third and fourth trenches CNT3 and CNT4 may be formed in the same step to be aligned with each other. A material for forming the third insulating layer 30 may be deposited onto the preliminary second insulating layer P-20 (see FIG. 20) so as to cover the second sub-metal layer MT-S2, and after this deposition, the third and fourth trenches CNT3 and CNT4 may be formed together.

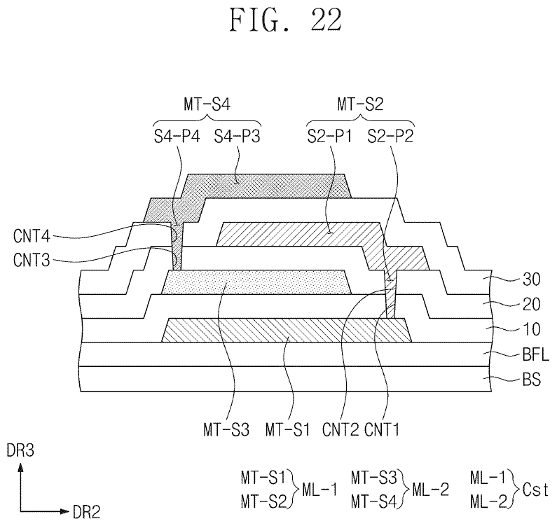

Referring to FIG. 22, a fourth sub-metal layer MT-S4 may be formed on the third insulating layer 30. The fourth sub-metal layer MT-S4 may fill the third and fourth trenches CNT3 and CNT4. A fourth portion S4-P4 of the fourth sub-metal layer MT-S4 may be located within the third and fourth trenches CNT3 and CNT4. A metal material may be deposited onto the third insulating layer 30, and the deposited metal material may be patterned to form the fourth portion S4-P4 of the fourth sub-metal layer MT-S4.

A method for manufacturing a display panel according to an embodiment may include forming a sub-metal layer (i.e., second and fourth sub-metal layers) including one portion (i.e., a first portion and a third portion) and the other portion (i.e., a second portion and a fourth portion) extending from the one portion, thereby exhibiting excellent processibility. A display panel according to an embodiment manufactured using the method for manufacturing the display panel may include a capacitor having a folded shape. The capacitor may include first and second metal layers. Each of the first and second metal layers may have a folded shape in a cross-section including three non-folding portions and two folding portions. The first metal layer may include a first sub-metal layer, and a second sub-metal layer disposed on the first sub-metal layer, and the first and second sub-metal layers may be arranged to have a folded shape in a cross-section. The second metal layer may include a third sub-metal layer, and a fourth sub-metal layer at least partially disposed on the third sub-metal layer, and the third and fourth sub-metal layers may be arranged to have a folded shape in a cross-section. The capacitor including the first and second metal layers each having the folded shape may have increased in surface area compared to typical capacitors, thereby exhibiting high-capacity characteristics. Accordingly, the display panel according to an embodiment including the capacitor exhibiting the high-capacity characteristics may exhibit excellent display quality. In an embodiment, an electronic apparatus including the display panel may exhibit excellent reliability due to decreased chances of foreign matter defects during manufacturing.

The display panel and the electronic apparatus including the display panel according to the embodiment may include the capacitor including the second and fourth sub-metal layers, thereby exhibiting excellent reliability and excellent display quality.

The method for manufacturing the display panel according to the embodiment may include the forming of the second and fourth sub-metal layers to manufacture the display panel exhibiting the excellent manufacturability.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the disclosure set forth in the claims to be described later.

Therefore, the technical scope of the disclosure is not to be limited to the contents stated in the detailed description of the specification but should be determined by the claims.

What is claimed is:

1. A display panel comprising a base layer, a circuit layer disposed on the base layer, and a display element layer disposed on the circuit layer,
wherein the circuit layer comprises first to third insulating layers, a capacitor comprising first and second metal layers, and a transistor,
wherein a first trench is defined in the first insulating layer,
wherein the second insulating layer is disposed on the first insulating layer, and second and third trenches spaced apart from each other in a first direction perpendicular to a thickness direction are defined in the second insulating layer,
wherein the third insulating layer is disposed on the second insulating layer, and a fourth trench is defined in the third insulating layer,
wherein the first trench and the second trench are aligned with each other, and the third trench and the fourth trench are aligned with each other,
wherein the first metal layer comprises a first sub-metal layer and a second sub-metal layer at least partially disposed on the first sub-metal layer,
wherein the second sub-metal layer comprises a first portion separated from the first sub-metal layer with the first and second insulating layers disposed between the first portion and the first sub-metal layer, and a second portion which extends from the first portion and is disposed within the first and second trenches,
wherein the second metal layer comprises a third sub-metal layer disposed over the first sub-metal layer, and a fourth sub-metal layer at least partially disposed on the third sub-metal layer,
wherein the fourth sub-metal layer comprises a third portion separated from the third sub-metal layer with the second and third insulating layers disposed between the third portion and the third sub-metal layer, and a fourth portion which extends from the third portion and is disposed within the third and fourth trenches,
wherein each of the second portion and the fourth portion extends on a plane in a second direction perpendicular to the thickness direction.

2. The display panel of claim 1, wherein the second portion of the second sub-metal layer is disposed between the first sub-metal layer and the first portion of the second sub-metal layer, and electrically connects the first sub-metal layer to the first portion of the second sub-metal layer.

3. The display panel of claim 1, wherein the fourth portion of the fourth sub-metal layer is disposed between the third sub-metal layer and the third portion of the fourth sub-metal layer, and electrically connects the third sub-metal layer to the third portion of the fourth sub-metal layer.

4. The display panel of claim 1, wherein the first portion of the second sub-metal layer is disposed on a different layer from the third portion of the fourth sub-metal layer.

5. The display panel of claim 1, wherein the first portion of the second sub-metal layer and the fourth portion of the fourth sub-metal layer are separated from each other in the first direction, with one area of the third insulating layer disposed between the first portion and the fourth portion.

6. The display panel of claim 1, wherein the third sub-metal layer and the second portion of the second sub-metal layer are separated from each other in the first direction, with one area of the second insulating layer disposed between the third sub-metal layer and the second portion.

7. The display panel of claim 1, wherein each of the first to third insulating layers has a single-layer structure.

8. The display panel of claim 1, wherein the first insulating layer has a single-layer structure, and the first insulating layer is directly disposed between the first sub-metal layer and the third sub-metal layer.

9. The display panel of claim 1, wherein the second insulating layer has a single-layer structure, and the second insulating layer is directly disposed between the third sub-metal layer and the first portion of the second sub-metal layer.

10. The display panel of claim 1, wherein the third insulating layer has a single-layer structure, and the third insulating layer is directly disposed between the first portion of the second sub-metal layer and the third portion of the fourth sub-metal layer.

11. The display panel of claim 1, wherein the transistor comprises an oxide semiconductor pattern and a gate electrode disposed over the oxide semiconductor pattern.

12. The display panel of claim 11, wherein the gate electrode is at least a part of the first sub-metal layer.

13. The display panel of claim 11, wherein the gate electrode, the first portion of the second sub-metal layer, the third sub-metal layer, and the third portion of the fourth sub-metal layer overlap each other.

14. The display panel of claim 1, wherein the display element layer comprises a light emitting element, and a pixel defining film in which an emission opening is defined,
wherein the light emitting element comprises a first electrode having at least a portion in the emission opening, a second electrode disposed over the first electrode, and an emission layer disposed between the first electrode and the second electrode.

15. A method for manufacturing a display panel, the method comprising:
preparing a base layer;
forming, on the base layer, a circuit layer comprising first to third insulating layers, a capacitor comprising first and second metal layers, and a transistor; and
forming a display element layer on the circuit layer,
wherein the first metal layer comprises a first sub-metal layer and a second sub-metal layer at least partially disposed on the first sub-metal layer,
wherein the second metal layer comprises a third sub-metal layer at least partially disposed over the first sub-metal layer, and a fourth sub-metal layer disposed on the third sub-metal layer,
wherein the forming of the circuit layer comprises:
forming the first sub-metal layer on the base layer;
forming a preliminary first insulating layer on the first sub-metal layer;
forming the third sub-metal layer on the preliminary first insulating layer;
forming the first insulating layer, in which a first trench is defined, from the preliminary first insulating layer, and forming, over the third sub-metal layer, a preliminary second insulating layer having a second trench aligned with the first trench;
forming the second sub-metal layer on the preliminary second insulating layer including filling the first trench and the second trench with material of the second sub-metal layer;
forming the second insulating layer from the preliminary second insulating layer having the second trench and a third trench, and forming, on the second sub-metal layer, the third insulating layer having a fourth trench; and
forming the fourth sub-metal layer on the third insulating layer including filling the third trench and the fourth trench,
wherein the second trench and the third trench are spaced apart from each other in a first direction perpendicular to a thickness direction,
wherein the second sub-metal layer comprises a first portion which is separated from the first sub-metal layer with the first and second insulating layers disposed between the first portion and the first sub-metal layer, and a second portion which extends from the first portion and is disposed within the first and second trenches,
wherein the fourth sub-metal layer comprises a third portion which is separated from the third sub-metal layer with the second and third insulating layers disposed between the third portion and the third sub-metal layer, and a fourth portion which extends from the third portion and is disposed within the third and fourth trenches,
wherein each of the second portion and the fourth portion extends on a plane in a second direction perpendicular to the thickness direction.

16. The method of claim 15, wherein each of the first to third insulating layers has a single-layer structure.

17. The method of claim 15, wherein the first portion of the second sub-metal layer is disposed on a different layer from the third portion of the fourth sub-metal layer.

18. An electronic apparatus comprising a display panel configured to provide an image, and a processor,
wherein the display panel comprises a base layer, a circuit layer disposed on the base layer, and a display element layer disposed on the circuit layer,
wherein the circuit layer comprises first to third insulating layers, a capacitor comprising first and second metal layers, and a transistor,
wherein a first trench is defined in the first insulating layer,
wherein the second insulating layer is disposed on the first insulating layer, and second and third trenches spaced apart from each other in a first direction perpendicular to a thickness direction are defined in the second insulating layer,
wherein the third insulating layer is disposed on the second insulating layer, and a fourth trench is defined in the third insulating layer,
wherein the first trench and the second trench are aligned with each other, and the third trench and the fourth trench are aligned each other,
wherein the first metal layer comprises a first sub-metal layer and a second sub-metal layer disposed on the first sub-metal layer,
wherein the second sub-metal layer comprises a first portion which is separated from the first sub-metal layer with the first and second insulating layers disposed between the first portion and the first sub-metal layer, and a second portion which extends from the first portion and is disposed within the first and second trenches,
wherein the second metal layer comprises a third sub-metal layer disposed over the first sub-metal layer, and a fourth sub-metal layer at least partially disposed on the third sub-metal layer,
wherein the fourth sub-metal layer comprises a third portion which is separated from the third sub-metal layer with the second and third insulating layers disposed between the third portion and the third sub-metal layer, and a fourth portion which extends from the third portion and is disposed within the third and fourth trenches,
wherein each of the second portion and the fourth portion extends on a plane in a second direction perpendicular to the thickness direction.

19. The electronic apparatus of claim 18, wherein the first portion of the second sub-metal layer is disposed on a different layer from the third portion of the fourth sub-metal layer.

20. The electronic apparatus of claim 18, wherein the second portion of the second sub-metal layer is disposed between the first sub-metal layer and the first portion of the second sub-metal layer, and electrically connects the first sub-metal layer to the first portion of the second sub-metal layer.
